(19) United States
(12) Patent Application Publication
(10) Pub. No.: US 2026/0123068 A1
(43) Pub. Date: Apr. 30, 2026

(54) IMAGE SENSOR

(71) Applicant: Samsung Electronics Co., Ltd., Suwon-si (KR)

(72) Inventors: Jihun Kim, Suwon-si (KR); Sungsoo Choi, Suwon-si (KR); Hojeong Lee, Suwon-si (KR)

(21) Appl. No.: 19/266,959

(22) Filed: Jul. 11, 2025

(30) Foreign Application Priority Data
Oct. 25, 2024 (KR) 10-2024-0147531

(51) Int. Cl. H10F 39/00; H10F 39/18

(52) U.S. Cl. CPC H10F 39/8027; H10F 39/182; H10F 39/80373; H10F 39/807

(57) ABSTRACT

An example image sensor includes a substrate having a first surface and a second surface opposite to each other, a photoelectric conversion portion in the substrate, a pixel circuit adjacent to the first surface of the substrate, and an isolation pattern that extends through at least a portion of the substrate and includes an isolation portion. The isolation portion defines a region where the photoelectric conversion portion is disposed. The pixel circuit includes a first transistor. The first transistor includes a first transfer transistor and a second transfer transistor. The substrate includes an active region that is adjacent to the first surface of the substrate and includes a first active region. The first active region includes a first active portion, a second active portion, and a connection active portion that connects the first active portion and the second active portion in a first diagonal direction inclined to the isolation portion.

### CROSS-REFERENCE TO RELATED APPLICATION

This application claims priority to and the benefit of Korean Patent Application No. 10-2024-0147531 filed in the Korean Intellectual Property Office on October 25, 2024, the entire contents of which are incorporated herein by reference.

### BACKGROUND

An image sensor is a semiconductor device that converts optical images into electrical signals. The image sensors may be classified into charge coupled device (CCD) type image sensors based on silicon semiconductors and complementary metal oxide semiconductor (CMOS) type image sensors (CIS).

Among these, the CMOS type image sensors may be driven by a simple method and a signal processing circuit may be integrated on a single chip in the CMOS type image sensors. Therefore, the CMOS type image sensors may be downsized and have a low power consumption, and thus, may be applied to products with a limited battery capacity. With the advancement of the electronics industry, various studies have been conducted to improve the performance of the CMOS type image sensors.

### SUMMARY

The present disclosure relates to an image sensor capable of enhancing performance and productivity.

In general, according to some aspects, an image sensor includes a substrate that has a first surface and a second surface opposite to each other, a photoelectric conversion portion in the substrate, a pixel circuit adjacent to the first surface of the substrate, and an isolation pattern that penetrates at least a portion of the substrate and includes an isolation portion. The isolation portion defines a region where the photoelectric conversion portion is disposed. The pixel circuit includes a first transistor. The first transistor includes a first transfer transistor and a second transfer transistor. The substrate includes an active region that is adjacent to the first surface of the substrate and includes a first active region. The first active region includes a first active portion where the first transfer transistor is disposed, a second active portion where the second transfer transistor is disposed, and a connection active portion that connects the first active portion and the second active portion in a first diagonal direction inclined to the isolation portion.

In general, according to some aspects, an image sensor includes a substrate that has a first surface and a second surface opposite to each other, a photoelectric conversion portion in the substrate, a pixel circuit adjacent to the first surface of the substrate, and an isolation pattern that penetrates at least a portion of the substrate. The photoelectric conversion portion includes a first conversion portion and a second conversion portion. The first conversion portion is at a first side in a first direction, and the second conversion portion is at a second side opposite to the first side in the first direction. The pixel circuit includes a first transistor. The first transistor includes a first transfer transistor and a second transfer transistor. The first transfer transistor is electrically connected to the first conversion portion and is at a third side in a second direction that intersects the first direction. The second transfer transistor is electrically connected to the second conversion portion and is at a fourth side opposite to the third side in the second direction.

In general, according to some aspects, an image sensor includes a substrate, a plurality of pixel regions, and an isolation pattern. The substrate has a first surface and a second surface opposite to each other. Each of the plurality of pixel regions includes a photoelectric conversion portion in the substrate and a pixel circuit adjacent to the first surface of the substrate. The isolation pattern penetrates at least a portion of the substrate and includes an isolation portion. The isolation portion defines a region where the photoelectric conversion portion is disposed. The photoelectric conversion portion includes a first conversion portion and a second conversion portion. The first conversion portion is at a first side in a first direction, and the second conversion portion is at a second side opposite to the first side in the first direction. The pixel circuit has a point-symmetrical shape in one of the plurality of pixel regions, and has an asymmetrical shape in the first direction.

In general, according to some aspects, first and second transfer transistors may be disposed at opposite sides in a first diagonal direction and a first active region may extend in the first diagonal direction, and the first active region may have a symmetrical shape (e.g., a point-symmetrical shape) with respect to a first inner portion or a second inner portion of an isolation pattern. Further, second and third transistors may be disposed at opposite sides in a second diagonal direction. Accordingly, freedom of a layout of the second and third transistors and an area of the second and third transistors may increase, and an interval between the plurality of transistors may be secured. Thereby, performance and productivity of an image sensor may be enhanced.

### BRIEF DESCRIPTION OF THE DRAWINGS

FIG. 1 is a block diagram that schematically illustrates an example of an image sensor.

FIG. 2 is a circuit diagram of an example of a pixel array that is included in the image sensor illustrated in FIG. 1.

FIG. 3 is a partial cross-sectional view that illustrates an example of an image sensor.

FIG. 4 is a plan view that schematically illustrates an example of a plurality of pixel regions of the image sensor illustrated in FIG. 3.

FIG. 5 is a plan view that illustrates an example pixel region among the plurality of pixel regions PX of the image sensor illustrated in FIG. 4.

FIG. 6 is an example cross-sectional view taken along a line C-C’ in FIG. 5.

FIG. 7 is a plan view that schematically illustrates an example of a plurality of pixel regions of an image sensor.

FIG. 8 is a plan view that schematically illustrates an example of a plurality of pixel regions of an image sensor.

FIG. 9 is a plan view that schematically illustrates an example of a plurality of pixel regions of an image sensor.

FIG. 10 is a plan view that schematically illustrates an example of a plurality of pixel regions of an image sensor.

FIG. 11 is a plan view that schematically illustrates an example of a plurality of pixel regions of an image sensor.

FIG. 12 is a plan view that schematically illustrates an example of a plurality of pixel regions of an image sensor.

FIG. 13 is a plan view that schematically illustrates an example of a pixel region of an image sensor.

FIG. 14 is a plan view that schematically illustrates an example of a pixel region of an image sensor.

FIG. 15 is a partial cross-sectional view that illustrates an example of an image sensor.

### DETAILED DESCRIPTION

Implementations of the present disclosure will be described more fully hereinafter with reference to the accompanying drawings for those skilled in the art to which the present disclosure pertains to easily practice the present disclosure. The present disclosure may be implemented in various different forms and is not limited to the implementations provided herein.

A portion unrelated to the description is omitted in order to clearly describe the present disclosure, and same or similar components are denoted by a same reference numeral throughout the present specification.

Further, since sizes and thicknesses of portions, regions, members, units, layers, films, or the like., illustrated in the accompanying drawings may be arbitrarily illustrated for better understanding and convenience of explanation, the present disclosure is not limited to the illustrated sizes and thicknesses. In the drawings, thicknesses of portions, regions, members, units, layers, films, or the like., may be enlarged or exaggerated for convenience of explanation and/or simple illustration.

It will be understood that when a component such as a layer, film, region, or substrate is referred to as being “on” another component, it may be directly on other component or an intervening component may also be present. In contrast, when a component is referred to as being “directly on” another component, there is no intervening component present. Further, when a component is referred to as being “on” or “above” a reference component, a component may be positioned on or below the reference component, and does not necessarily be “on” or “above” the reference component toward an opposite direction of gravity.

In addition, unless explicitly described to the contrary, the word “comprise”, “include”, or “contain”, and variations such as “comprises”, “comprising”, “includes”, “including”, “contains” or “containing” will be understood to imply the inclusion of other components rather than the exclusion of any other components.

Further, throughout the specification, a phrase “on a plane”, “in a plane”, “on a plan view”, or “in a plan view” may indicate a case where a portion is viewed from above or a top portion, and a phrase “on a cross-section” or “in a cross-sectional view” may indicate a vertical cross-sectional viewed from a side.

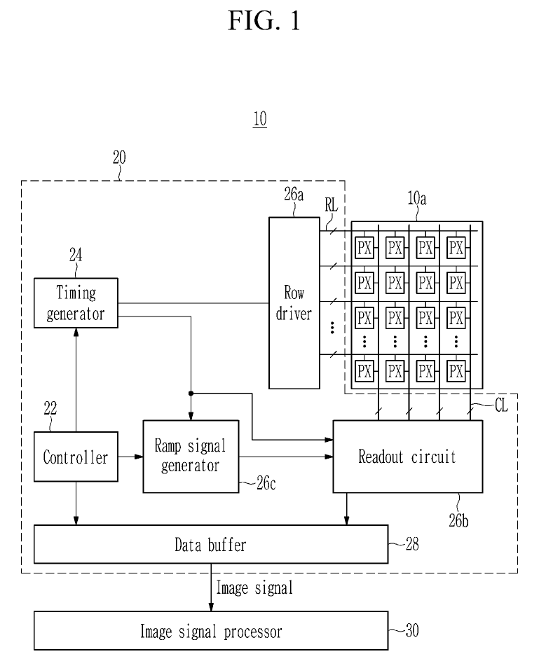

Hereinafter, an image sensor will be described in detail with reference to FIG. 1 to FIG. 6.

FIG. 1 is a block diagram that schematically illustrates an example of an image sensor 10.

Referring to FIG. 1, an image sensor 10 may include a pixel array 10a, and a logic circuit 20 that controls the pixel array 10a. The logic circuit 20 is a circuit configured to control the pixel array 10a and may include, for example, a controller 22, a timing generator 24, a row driver 26a, a readout circuit 26b, a ramp signal generator 26c, and a data buffer 28. The image sensor 10 may further include an image signal processor 30. In some implementations, the image signal processor 30 may be disposed outside the image sensor 10.

The image sensor 10 may generate an image signal by converting light received from an outside into an electric signal, and the image signal generated by the image sensor 10 may be provided to the image signal processor 30.

The image sensor 10 may be mounted on an electronic device with an image or light sensing function. For example, the image sensor 10 may be mounted on electronic devices such as cameras, smartphones, wearable devices, internet of things (IoT) devices, home appliance devices, tablets, personal digital assistants (PDA), portable multimedia players (PMP), navigations, drones, or advanced driver assistance systems (ADAS). In some implementations, the image sensor 10 may be mounted on an electronic device provided as a part of a vehicle, a furniture, a manufacturing facility, a door, or various measuring devices.

The pixel array 10a may include a plurality of pixel regions PX, and a plurality of row lines RL and a plurality of column lines CL respectively connected to the plurality of pixel regions PX.

In some implementations, each pixel region PX may include at least one photoelectric conversion device. The photoelectric conversion device may detect incident light and convert the incident light into the electric signal, that is, the plurality of analog pixel signals, according to an amount of the light. The photoelectric conversion device may be a photodiode, a photo transistor, a photo gate, or a pinned photo diode (PPD). In some implementations, the photoelectric conversion device may be a single-photon avalanche diode (SPAD) applied to a 3D sensor pixel. A level of the analog pixel signal output from the photoelectric conversion device may be proportional to an amount of the light provided to each pixel region PX or an amount of charges output from the photoelectric conversion device.

The plurality of row lines RL may extend in one direction and be connected to the plurality of pixel regions PX arranged in the one direction. For example, a control signal output from the row driver 26a to the row line RL may be transmitted to a gate of a transistor of the plurality of pixel regions PX that is connected to the row line RL. The column line CL may extend in a crossing direction that intersects the one direction and may be connected to the plurality of pixel regions PX arranged in the crossing direction. The plurality of pixel signals output from the plurality of pixel regions PX may be transmitted to the readout circuit 26b through the plurality of column lines CL.

In some implementations, the plurality of pixel regions PX may be grouped in a form of a plurality of columns and a plurality of rows to form one unit pixel group. That is, the plurality of pixel regions PX arranged in an extension direction of the row line RL and/or the plurality of pixel regions PX arranged in an extension direction of the column line CL may form one unit pixel group. For example, one unit pixel group may include a plurality of pixels arranged in a form of two columns and two rows, and one unit pixel group may output one analog pixel signal. However, the implementations are not limited thereto and various modifications are possible. In some implementations, one pixel region PX may constitute one unit pixel group.

In some implementations, each pixel region PX may include a pixel circuit that processes the charge generated by the photoelectric conversion device and outputs the electric signal. The pixel circuit may include a transfer transistor, a reset transistor, a selection transistor, a driving transistor, or the like. The implementations are not limited thereto and the pixel circuit may have any of various structures.

The controller 22 may generally control the timing generator 24, the row driver 26a, the readout circuit 26b, the ramp signal generator 26c, and the data buffer 28 included in the image sensor 10. For example, the controller 22 may control an operation timing by using a control signal. In some implementations, the controller 22 may receive a mode signal indicating an imaging mode from an application processor and generally control the image sensor 10 based on the received mode signal.

The timing generator 24 may generate a signal that serves as a reference for the operation timing of the image sensor 10. The timing generator 24 may provide a control signal that controls the timing of the row driver 26a, the readout circuit 26b, and the ramp signal generator 26c.

The row driver 26a may generate a control signal to drive the pixel array 10a in response to the control signal of the timing generator 24, and may provide the control signal to the plurality of pixel regions PX of the pixel array 10a through the plurality of row lines RL. For example, the row driver 26a may generate a transfer signal that controls the transfer transistor, a reset control signal that controls the reset transistor, and a selection control signal that controls the selection transistor, and provide the transfer signal, the reset control signal, and the selection signal to the pixel array 10a.

The readout circuit 26b may convert a pixel signal (or an electric signal) output through the corresponding column line CL into a pixel value representing the amount of light. The ramp signal generator 26c may generate a reference signal or a ramp signal and transmit the reference signal or the ramp signal to the readout circuit 26b. For example, the readout circuit 26b may convert the pixel signal to the pixel value by comparing the ramp signal and the pixel signal. The pixel value may be an image data with a plurality of bits.

The data buffer 28 may store the pixel value of the pixel region PX transmitted from the readout circuit 26b and may output the stored pixel value in response to a signal from the controller 22.

The image signal processor 30 may perform image-signal processing on the image signal received from the data buffer 28. For example, the image signal processor 30 may receive the plurality of image signals from the data buffer 28 and generate one image by combining the received image signals.

The implementations are not limited to the above descriptions, and a structure, a type, or the like of the image sensor 10 may be variously modified.

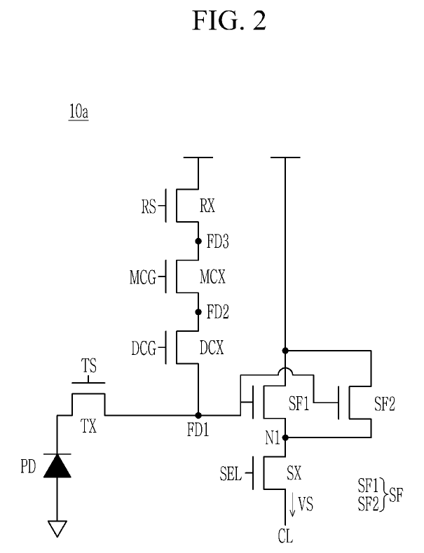

FIG. 2 is a circuit diagram of an example of the pixel array 10a that is included in the image sensor 10 illustrated in FIG. 1. .

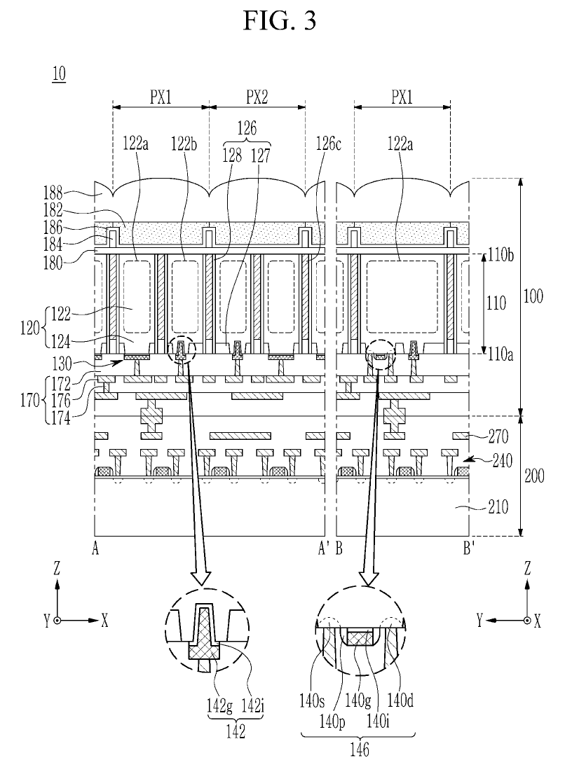

Referring to FIG. 2, the pixel array 10a may include a photoelectric conversion portion PD, a transfer transistor TX, a reset transistor RX, gain control transistors DCX and MCX, a driving transistor SF, and a selection transistor SX. The photoelectric conversion portion PD illustrated in FIG. 2 may be a photoelectric conversion portion 120 illustrated in FIG. 3.

The transfer transistor TX may be connected between the photoelectric conversion portion PD and a first floating diffusion node FD1. In response to a transfer control signal TS applied to a gate of the transfer transistor TX, the transfer transistor TX may transfer charges generated in the photoelectric conversion portion PD to the first floating diffusion node FD1.

The gain control transistor DCX or MCX may be connected between the first floating diffusion node FD1 and the reset transistor RX. The gain control transistor DCX or MCX may be controlled by a gain control signal DCG or MCG. The gain control transistor DCX or MCX may be a transistor that reduces a conversion gain, which is a rate at which charges are converted into a voltage, by controlling capacitance. In some implementations, the gain control transistor DCX or MCX may be included in plural. For example, the gain control transistor DCX or MCX may include a first gain control transistor DCX and a second gain control transistor MCX. The first gain control transistor DCX may be connected between the first floating diffusion node FD1 and a second floating diffusion node FD2, and the second gain control transistor MCX may be connected between the second floating diffusion node FD2 and a third floating diffusion node FD3. According to turn-on or turn-off of the first gain control transistor DCX and the second gain control transistor MCX, the image sensor 10 may operate in a low conversion gain (LCG) mode, a middle conversion gain (MCG) mode, or a high conversion gain (HCG) mode.

The reset transistor RX may be connected between a power voltage line that supplies a power voltage and the third floating diffusion node FD3. When a reset control signal RS is applied to the reset transistor RX, the charges that are accumulated in the third floating diffusion node FD3 may be reset. When the reset control signal RS is applied to the reset transistor RX and the first and/or second gain control transistor DCX and/or MCX is turned on, the charges accumulated in the first floating diffusion node FD1 and/or the second floating diffusion node FD2 may be reset.

However, the implementations are not limited thereto. For example, the pixel array 10a may include one of the first gain control transistor DCX and the second gain control transistor MCX, and may not include the other of the first gain control transistor DCX and the second gain control transistor MCX. In some implementations, the pixel array 10a may not include the gain control transistor DCX or MCX. When the gain control transistor DCX or MCX is not included, an end of the reset transistor RX may be directly connected to the first floating diffusion node FD1.

A gate of the driving transistor SF may be connected to the first floating diffusion node FD1. The driving transistor SF may be a source follower buffer amplifier. The driving transistor SF may perform buffering of a signal according to an amount of charges accumulated in the first floating diffusion node FD1. The driving transistor SF may amplify a potential change at the first floating diffusion node FD1 and output the amplified result to a first output node N1. In FIG. 2, it is illustrated as an example that the driving transistor SF includes a first driving transistor SF1 and a second driving transistor SF2 coupled in parallel. However, the implementations are not limited thereto, and one driving transistor SF may be included.

The selection transistor SX may be connected between the output node N1 and a column line CL. The selection transistor SX may output a pixel signal VS to the column line CL in respond to a selection control signal SEL.

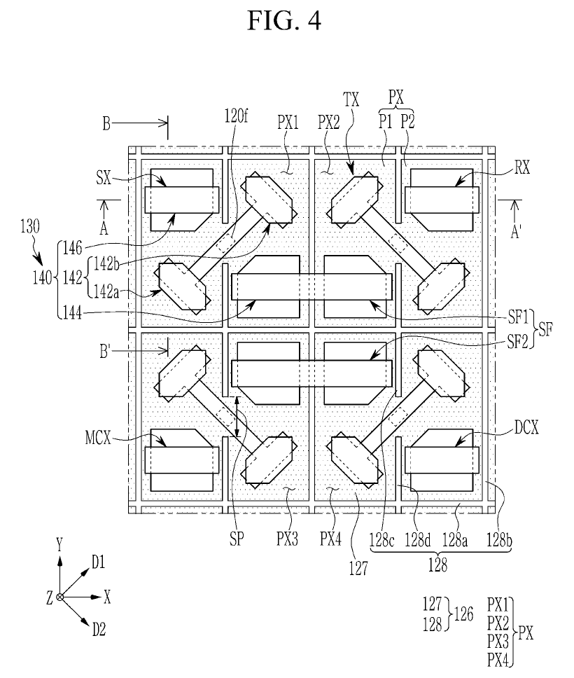

FIG. 3 is a partial cross-sectional view that illustrates an example of an image sensor 10. FIG. 4 is a plan view that schematically illustrates an example of a plurality of pixel regions PX of the image sensor 10 illustrated in FIG. 3. FIG. 3 is a cross-sectional view taken along an A-A’ line and a B-B’ in FIG. 4. FIG. 4 is a rear plan view that illustrates a first surface 110a of a substrate 110 that is adjacent to a wiring portion 170. For a clear understanding, in FIG. 4, gate electrodes 140g are mainly illustrated for second and third transistors 144 and 146.

Referring to FIG. 3 and FIG. 4, in some implementations, an image sensor 10 may include a substrate 110, a photoelectric conversion portion 120 that is disposed in the substrate 110, a pixel circuit 130, and an isolation pattern 126. The substrate 110 may have a first surface 110a and a second surface 110b that are opposite to each other. The pixel circuit 130 may be disposed at a portion that is adjacent to the first surface 110a of the substrate 110. The isolation pattern 126 may penetrate or pass through at least a portion of the substrate 110.

In some implementations, the substrate 110 may include a semiconductor substrate that includes or is formed of a semiconductor material. For example, the substrate 110 may include a bulk substrate that includes or is formed of a semiconductor material, a substrate that includes a bulk substrate and an epitaxial layer on the bulk substrate, or a semiconductor-on-insulator. In this instance, the semiconductor material included in the substrate 110 may have a second conductivity type (e.g., a p-type or an n-type) that is opposite to a conductivity type of a first conductivity type region 122.

The semiconductor material included in the substrate 110 may include or be formed of at least one of a group IV semiconductor, a group III-V compound semiconductor, or a group II-VI compound semiconductor. For example, the semiconductor material that is included in the substrate 110 may include or be formed of at least one of Si, Ge, SiGe, SiC, GaAs, InAs, GaP, InP, InSb, InGaAs, ZnTe, or CdS. For example, the bulk substrate may be a single-crystalline or polycrystalline semiconductor substrate and may include or be formed of Si, Ge, or SiGe. In some implementations, the semiconductor-on-insulator may be a silicon-on-insulator (SOI), a germanium-on-insulator (GOI), or a silicon-germanium-on- insulator (SGOI).

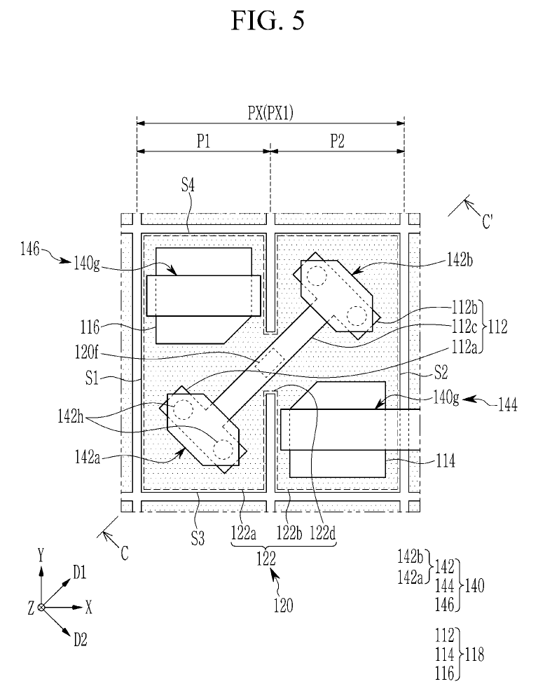

A doping region may be disposed at an active region 118 (refer to FIG. 5) that is adjacent to the first surface 110a of the substrate 110. For example, the doping region may be disposed at a partial portion of the substrate 110 adjacent to the first surface 110a. The doping region may include a floating diffusion region 120f, a ground region, or the like. For simple illustration, in FIG. 4, the floating diffusion region 120f is illustrated and the ground region is omitted.

The floating diffusion region 120f may have a first conductivity type opposite to the second conductivity type of the substrate 110, and charges generated by the photoelectric conversion portion 120 may be accumulated in the floating diffusion region 120f. A position, an electrical connection structure, or the like of the floating diffusion region 120f will be described later in more detail. The ground region may have a conductivity type same as the second conductivity type of the substrate 110, and may have a doping concentration higher than a doping concentration of the substrate 110 or a second conductivity type region 124. A ground voltage may be applied to the ground region. The ground region may be disposed in a portion of an active region 118.

However, the implementations are not limited thereto. The floating diffusion region 120f and/or the ground region may be omitted. In some implementations, an additional doping region other than the floating diffusion region 120f and/or the ground region may be further included.

In some implementations, the image sensor 10 may include a plurality of pixel regions PX. Each of the plurality of pixel regions PX may include the photoelectric conversion portion 120 in the substrate 110 and the pixel circuit 130 adjacent to the first surface 110a of the substrate 110.

In some implementations, the plurality of pixel regions PX may include a first pixel region PX1, a second pixel region PX2, a third pixel region PX3, and a fourth pixel region PX4. The first pixel region PX1 and the second pixel region PX2 may be adjacent to each other in a first direction (an X-axis direction in the drawings). The third pixel region PX3 and the fourth pixel region PX4 may be adjacent to the first pixel region PX1 and the second pixel region PX2, respectively, in a second direction (a Y-axis direction in the drawings) that intersects the first direction (the X-axis direction in the drawings). For example, the first pixel region PX1, the second pixel region PX2, the third pixel region PX3, and the fourth pixel region PX4 illustrated in FIG. 4 may be one unit pixel group, but the implementations are not limited thereto.

The photoelectric conversion portion 120 in the substrate 110 may convert light incident from an outside to an electrical signal.

For example, the photoelectric conversion portion 120 may include a first conductivity type region 122 and a second conductivity type region 124. The first conductivity type region 122 may include a first conductivity type dopant to have a first conductivity type (e.g., an n-type or a p-type) that is opposite to a conductive type of the substrate 110. The second conductivity type region 124 may include a second conductivity type dopant to have a second conductivity type (e.g., a p-type or an n-type) that is opposite to the first conductive type. The first conductivity type region 122 may be formed by doping the first conductivity type dopant to a portion of the substrate 110. The second conductivity type region 124 may be formed by doping the second conductivity type dopant to a portion of the substrate 110 that is adjacent to the first surface 110a of the substrate 110. In some implementations, the second conductivity type region 124 may be formed of a portion of the substrate 110 where the first conductivity type region 122 is not disposed. A photodiode may be constituted by a pn junction of the first conductivity type region 122 and the second conductivity type region 124. The photoelectric conversion portion 120 may generate and accumulate charges in proportion to an amount of light provided to each pixel region PX.

The isolation pattern 126 may penetrate or pass through at least a portion of the substrate 110 to define a region of the active region 118 and/or the photoelectric conversion portion 120. At least a portion of the isolation pattern 126 (e.g., at least a portion of a second isolation pattern 128) may be disposed to correspond to a boundary of each pixel region PX.

In some implementations, in a cross-sectional view, the isolation pattern 126 may penetrate or pass through at least a portion of the substrate 110 in a thickness direction (a Z-axis direction in the drawings). The isolation pattern 126 may include a first isolation pattern 127 and a second isolation pattern 128. The first isolation pattern 127 may be disposed adjacent to the first surface 110a of the substrate 110 and define the active region 118 in each pixel region PX. The second isolation pattern 128 may be disposed far away from the first surface 110a of the substrate 110 than the first isolation pattern 127 and define a region where the photoelectric conversion portion 120 is disposed.

In some implementations, the isolation pattern 126 may include the first isolation pattern 127 that has a relatively small depth and the second isolation pattern 128 that has a relatively large depth. For example, the first isolation pattern 127 may be a shallow trench isolation (STI) pattern, and the second isolation pattern 128 may be a deep trench isolation (DTI) pattern. In a plan view, the second isolation pattern 128 penetrates a portion (e.g., an inner portion) of the first isolation pattern 127, but the implementations are not limited thereto.

In some implementations, the second isolation pattern 128 may include a front deep trench isolation (FDTI) that includes a portion adjacent to the first surface 110a of the substrate 110 and/or a back deep trench isolation (BDTI) that includes a portion adjacent to the second surface 110b of the substrate 110. In the drawing, it is illustrated as an example that the second isolation pattern 128 includes the front deep trench isolation and entirely penetrates the substrate 110, but the implementations are not limited thereto.

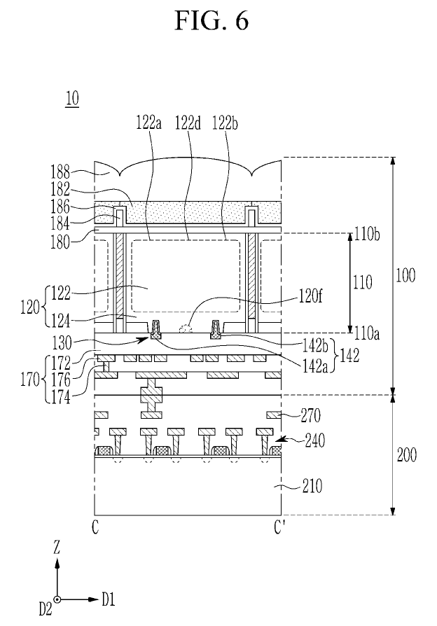

In a cross-sectional view, a first isolation portion of the isolation pattern 126 adjacent to the first surface 110a of the substrate 110 may define the active region 118 in a portion adjacent to the first surface 110a of the substrate 110. For example, the first isolation portion of the isolation pattern 126 adjacent to the first surface 110a of the substrate 110 may disposed at a portion other than the active region 118 in the portion adjacent to the first surface 110a of the substrate 110. The active region 118 will be described in more detail with reference to FIG. 5 and FIG. 6.

In the drawings, it is illustrated as an example that the first isolation portion of the isolation pattern 126 adjacent to the first surface 110a of the substrate 110 includes the first isolation pattern 127 and the second isolation pattern 128. For a clear understanding, in the drawings, a boundary between the first isolation pattern 127 and the second isolation pattern 128 is illustrated. However, the implementations are not limited thereto. The first isolation portion of the isolation pattern 126 adjacent to the first surface 110a of the substrate 110 may be a single portion, or the boundary between the first isolation pattern 127 and the second isolation pattern 128 may not be confirmed and the first isolation of the isolation pattern 126 may be regarded as a single portion.

A second isolation portion of the isolation pattern 126 that is far away from the first surface 110a of the substrate 110 than the first isolation portion of the isolation pattern 126 may define a region where the photoelectric conversion portion 120 is disposed.

For example, the second isolation portion of the isolation pattern 126 or the second isolation pattern 128 may include a first extension portion 128a and a second extension portion 128b. The first extension portion 128a may extend in the first direction (the X-axis direction in the drawings), and the second extension portion 128b may extend in the second direction (the Y-axis direction in the drawings). The first extension portion 128a and the second extension portion 128b may disposed to correspond to a boundary of each pixel region PX. For example, in a plan view, the second isolation portion of the isolation pattern 126 or the second isolation pattern 128 may have a lattice shape to correspond to the boundary of the plurality of pixel regions PX. Thereby, in a plan view, a pair of first extension portions 128a may extend in the first direction at opposite sides of each pixel region PX in the second direction, and a pair of second extension portions 128b may extend in the second direction at opposite sides of each pixel region PX in first direction. In a plan view, the photoelectric conversion portion 120 in each pixel region PX may be surrounded by the pair of first extension portions 128a and the pair of second extension portions 128b.

In some implementations, the isolation pattern 126 (e.g., the second isolation pattern 128) may further include first and second inner portions 128c and 128d that extend inside the pixel region PX. For example, the first and second inner portions 128c and 128d may extend from the pair of first extension portions 128a, respectively, and may extend between a first portion P1 (refer to FIG. 5) and a second portion P2 (refer to FIG. 5) or between a first conversion portion 122a and a second conversion portion 122b. The first inner portion 128c and the second inner portion 128d may face each other while interposing a separation portion SP in the pixel region PX. For example, the separation portion SP may be disposed at a center region of each pixel region PX, and the first inner portion 128c and the second inner portion 128d may be spaced apart from each other at the center region.

In some implementations, the first and second inner portions 128c and 128d may extend inside the pixel region PX and form a boundary between the first portion P1 and the second portion P2 (refer to FIG. 5) in the pixel region PX. This will be described in more detail with reference to FIG. 5 and FIG. 6.

The isolation pattern 126 may include an insulating material layer. The insulating material layer of the isolation pattern 126 may include or be formed of at least one of silicon oxide, silicon nitride, or silicon oxynitride, and may include a single layer or a plurality of layers. However, the implementations are not limited thereto. A material of the insulating material layer of the isolation pattern 126 may be variously modified. In some implementations, when the first isolation pattern 127 and the second isolation pattern 128 include a same material, the first isolation portion of the separation pattern 126 adjacent to the first surface 110a of the substrate 110 may entirely include a same material. In some implementations, when the first isolation pattern 127 and the second isolation pattern 128 include different materials, the boundary between the first isolation pattern 127 and the second isolation pattern 128 may be seen or confirmed in the first isolation portion of the separation pattern 126 adjacent to the first surface 110a of the substrate 110. In some implementations, a layer that is included in the first isolation pattern 127 may be seen or confirmed in the first isolation portion of the separation pattern 126 adjacent to the first surface 110a of the substrate 110. However, the implementations are not limited thereto.

In some implementations, the isolation pattern 126 may further include a conductive layer 126c. For example, the conductive layer 126c of the isolation pattern 126 may include or be formed of a semiconductor material (e.g., silicon). A dark current may be improved through a hole accumulation induced by a negative voltage applied to the conductive layer 126c of the isolation pattern 126. However, the implementations are not limited thereto. The negative voltage may not be applied to the conductive layer 126c of the isolation pattern 126, or the isolation pattern 126 may not include the conductive layer 126c.

A sidewall doping region may be disposed at a portion of the substrate 110 that is adjacent to the isolation pattern 126 (e.g., the second isolation pattern 128). Sidewall doping regions may be disposed at portions adjacent to both sidewalls of the isolation pattern 126 (e.g., the second isolation pattern 128), respectively. The sidewall doping region may improve the dark current, together with the conductive layer 126c of the isolation pattern 126. The sidewall doping region may have the second conductivity type (the p-type or the n-type) that is same as a conductivity type of the substrate 110. For example, the sidewall doping region may have the p-type. For example, the sidewall doping region may include boron, aluminum, gallium, indium, or the like as the p-type dopant.

In FIG. 3, it is illustrated as an example that a surface of the isolation pattern 126 that is adjacent to the first surface 110a of the substrate 110 is disposed on a same plane as the first surface 110a of the substrate 110. However, the implementations are not limited thereto, and the first surface 110a of the substrate 110 and the surface the isolation pattern 126 may be disposed on different planes.

The pixel circuit 130 that is adjacent to the first surface 110a of the substrate 110 may include a plurality of transistors 140. The pixel circuit 130 and the transistor 140 that is included in the pixel circuit 130 will be described later in more detail.

A wiring portion 170 that is electrically connected to the pixel circuit 130 may be disposed on the first surface 110a of the substrate 110. That is, the wiring portion 170 may be disposed to be adjacent to the first surface 110a of the substrate 110, which is opposite to the second surface 110b of the substrate 110 to which the light is incident, and thus, the wiring portion 170 may not be disposed in a path of the light incident to the image sensor 10. Thereby, light interference caused by the wiring portion 170 may be minimized.

The wiring portion 170 may include one or a plurality of wiring layers 176 that are electrically connected to the pixel circuit 130 through a contact via 174 that passes through or penetrates an interlayer insulation layer 172. The wiring layer 176 and the contact via 174 may be connected to form a desired circuit. The contact via 174 may be formed in a same process as the wiring layer 176, or may be formed in a separate process from the wiring layer 176.

The interlayer insulation layer 172 may include or be formed of an insulating material. For example, the interlayer insulation layer 172 may include or be formed of silicon oxide, silicon nitride, silicon oxynitride, and/or a low dielectric constant material. The low dielectric constant material may be a material having a dielectric constant lower than a dielectric constant of silicon oxide.

The wiring layer 176 or the contact via 174 may include or be formed of at least one of metal, a metal alloy, metal nitride, metal silicide, or a doped semiconductor material. The metal or the metal alloy may include or be formed of at least one of tungsten, molybdenum, titanium, tantalum, aluminum, copper, nickel, ruthenium, or cobalt, and the metal nitride may include or be formed of at least one of tungsten nitride, molybdenum nitride, titanium nitride, or tantalum nitride. The wiring layer 176 or the contact via 174 may further include metal oxide or metal oxynitride in which the above material is oxidized. The wiring layer 176 or the contact via 174 may include a single layer or a plurality of layers.

However, the implementations are not limited thereto. The interlayer insulation layer 172 may include or be formed of any of various insulating materials, and the wiring layer 176 or the contact via 174 may include or be formed of any of various conductive materials.

A horizontal insulation layer 180, a color filter 182, a filter separator 184, a protection layer 186, and a micro lens 188 may be disposed on the second surface 110b of the substrate 110.

More particularly, the horizontal insulation layer 180 may be disposed on the second surface 110b of the substrate 110. The horizontal insulation layer 180 may be disposed to cover the second surface 110b of the substrate 110 and the isolation pattern 126. The horizontal insulation layer 180 may act as a kind of a planarization layer configured to planarize a surface so that the color filter 182, the micro lens 188, or the like disposed on the horizontal insulation layer 180 is stably formed.

The horizontal insulation layer 180 may include or be formed of any of various insulating materials. For example, the horizontal insulation layer 180 may include or be formed of oxide, nitride, oxynitride, or fluoride including at least one of hafnium, zirconium, aluminum, tantalum, titanium, yttrium, cerium, lanthanum, neodymium, praseodymium, ytterbium, or silicon. For example, the horizontal insulation layer 180 may act as an anti-reflection layer, but the implementations are not limited thereto.

In some implementations, the horizontal insulation layer 180 may include a plurality of layers including different materials and having different thicknesses. For example, in the horizontal insulation layer 180, a first horizontal insulation layer adjacent to the second surface 110b of the substrate 110 may be a fixed charge layer having a negative fixed charge. Thereby, the dark current may be improved by a hole accumulation at a periphery of the fixed charge layer. In some implementations, the first horizontal insulation layer may include or be formed of metal oxide or metal fluoride including at least one of hafnium, zirconium, aluminum, tantalum, titanium, or yttrium. For example, the horizontal insulation layer 180 or the anti-reflection layer may include a first horizontal insulation layer including hafnium oxide, a second horizontal insulation layer including silicon oxide or silicon nitride, and a third horizontal insulation layer including hafnium oxide.

However, the implementations are not limited to thereto, and a number, a thickness, or the like of a layer included in the horizontal insulation layer 180 may be variously modified. In some implementations, a structure configured to reflect light may be disposed at the second surface 110b of the substrate 110. For example, a nanoporous structure that has a nanometer-level size may be formed at the second surface 110b of the substrate 110 by using laser or etching, thereby reflecting the light. The nanometer-level size may refer to a size (e.g., an average width, an average diameter, or an average pitch) of less than 1um. Thereby, the anti-reflection layer may be omitted in the horizontal insulation layer 180 and a manufacturing process may be simplified. However, the implementations are not limited thereto. In some implementations, when the structure configured to reflect the light is disposed at the second surface 110b of the substrate 110, the horizontal insulation layer 180 may include the anti-reflection layer.

The filter separator 184 may be disposed on the horizontal insulation layer 180. In some implementations, the filter separator 184 may surround at least a partial portion of the color filter 182. For example, the filter separator 184 may have a lattice structure that is same as or similar to the lattice structure of the isolation pattern 126, but the implementations are not limited thereto. The filter separator 184 may be referred to as a fence pattern or a grid pattern.

The filter separator 184 may prevent light that is incident obliquely into the color filter 182 in one of the plurality of pixel regions PX from entering another color filter 182 in an adjacent pixel region PX. Accordingly, a crosstalk between the plurality of pixel regions PX may be prevented.

In some implementations, the filter separator 184 may include or be formed of a material having a refractive index smaller than a refractive index of the color filter 182 or silicon oxide, or a material having a refractive index of about 1.0 to about 1.4. When the filter separator 184 includes a material with a small refractive index in the above, the light incident on the filter separator 184 may be totally reflected and directed toward an inside of the pixel region PX.

For example, the filter separator 184 may include or be formed of polymethyl methacrylate (PMMA), silicon acrylate, cellulose acetate butyrate (CAB), silica, or fluorine-silicon acrylate (FSA). For example, the filter separator 184 may include or be formed of a polymer material in which silica particles are dispersed. However, the implementations are not limited to thereto, and the filter separator 184 may include a material different from the above material.

The color filter 182 may be disposed on the horizontal insulation layer 180. The plurality of color filters 182 may be separated from each other by the filter separator 184. A plurality of color filters 182 may include, for example, a green filter, a blue filter, and a red filter. In some implementations, the plurality of color filters 182 may include a cyan filter, a magenta filter, a yellow filter, an infrared filter to allow infrared light to pass through, or the like. In some implementations, a pixel region PX where all visible light is incident may be provided.

The protection layer 186 may be disposed on the color filter 182 and/or the filter separator 184. In FIG. 3, it is illustrated as an example that the protection layer 186 is disposed between the filter separator 184 and the color filter 182 on the filter separator 184. The protection layer 186 may include or be formed of any of various materials such as an organic material, silicon oxide, silicon oxynitride, aluminum oxide, or the like. However, the implementations are not limited to a material of the protection layer 186. The protection layer 186 may be omitted, or the protection layer 186 may be disposed on the color filter 182 and the filter separator 184.

The micro lens 188 that is disposed on the color filter 182 and/or the protection layer 186 may include or be formed of a portion having a convex shape to converge or concentrate light incident to the pixel region PX. The micro lens 188 may include or be formed of any or various resin materials, for example, a styrene-based resin, an acryl-based resin, a styrene-acryl copolymer resin, a siloxane-based resin, or the like.

However, the implementations are not limited to thereto, and a shape, a material, or the like of the micro lens 188 may be variously modified. In some implementations, a meta lens may be included instead of the micro lens 188. The meta lens may include a nano structure of a nano rod or a nano pillar that has a nanometer-level size. In the meta lens, by a meta surface including meta atoms that are smaller than a wavelength of light uniformly or periodically, a direction of incident light may be changed so that the light reaches a specific point. Thereby, the meta lens may act as a lens. The meta lens or the nano structure may include or be formed of Si, SiN, GaN, TiO₂, or the like.

In FIG. 3, it is illustrated as an example that one micro lens 188 corresponds to each pixel region PX. However, the implementations are not limited thereto. In some implementations, one micro lens 188 may correspond to a plurality of pixel regions PX. In some implementations, one micro lens 188 may correspond to a portion of the pixel region PX. In some implementations, a protective layer or the like may be further disposed on an outer surface of the micro lens 188.

In FIG. 3, it is illustrated as an example that the filter separator 184 corresponds to each pixel region PX. However, the implementations are not limited thereto, and other various modifications are possible.

In some implementations, in a plan view, a relative position between the pixel region PX and the color filter 182 and/or a relative position between the pixel region PX and the micro lens 188 may be different from each other in a central region of the image sensor 10 and in an edge region of the image sensor 10. That is, in a plan view, an area (e.g., a planar area) of a portion of the color filter 182 that overlaps the pixel region PX and/or an area (e.g., a planar area) of a portion of the micro lens 188 that overlaps the pixel region PX may be smaller in the edge region of the image sensor 10 than in the central region of the image sensor 10. For example, the area (e.g., the planar area) of the portion of the color filter 182 that overlaps the pixel region PX and/or the area (e.g., the planar area) of the portion of the micro lens 188 that overlaps the pixel region PX may decrease from the central region of the image sensor 10 to the edge region of the image sensor 10.

By adjusting the relative position between the pixel region PX and the color filter 182 and/or the relative position between the pixel region PX and the micro lens 188, an amount of the light that reaches the photoelectric conversion portion 120 of the pixel region PX may be maximized. For example, the micro lens 188, the color filter 182, and the photoelectric conversion portion 120 of the pixel region PX may be disposed to overlap each other in a direction where light passes. Since the light is incident obliquely in the edge region of the image sensor 10, the relative position between the pixel region PX and the color filter 182 and/or the relative position between the pixel region PX and the micro lens 188 may be adjusted so that the light that is incident obliquely reaches the photoelectric conversion portion 120 of the pixel region PX to a large amount.

An additional wiring portion 200 may be further disposed on a photoelectric conversion substrate 100 (e.g., the wiring portion 170). The additional wiring portion 200 may include a substrate 210, and a logic circuit portion, a power portion, or the like that includes a transistor 240, a wiring 270, or the like. As in the above, the image sensor 10 may have a multi-layered stacking structure that include the photoelectric conversion substrate 100 and the additional wiring portion 200. When the photoelectric conversion substrate 100 and the additional wiring portion 200 are included as in the above, congestion of wirings, circuit elements, or the like that are included in the pixel circuit 130, the wiring portion 170, and the additional wiring portion 200 may be reduced. Thereby, an integration degree and performance of the image sensor 10 may be enhanced.

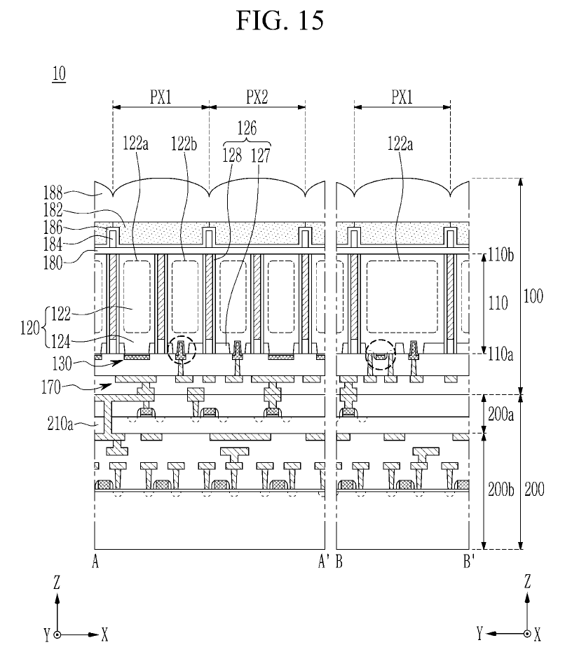

In FIG. 3, it is illustrated as an example that the image sensor 10 includes the photoelectric conversion substrate 100 and the additional wiring portion 200 and has a two-layered stacking structure. However, the implementations are not limited thereto. In some implementations, the wiring portion 170 on the substrate 110 may include a portion, a member, a wiring, or the like that is included in the additional wiring portion 200, and the image sensor 10 may include a single portion. However, the image sensor 10 may have a three-layered or more stacking structure. An implementation of an image sensor 10 that has a three-layered stacking structure will be described later in detail with reference to FIG. 15.

In the image sensor 10, the light incident from an outside may be converged or concentrated by the micro lens 188 and incident on the photoelectric conversion portion 120 through the color filter 182. The light incident on the photoelectric conversion portion 120 may be converted into an electric signal according to an amount of the light.

Referring to FIG. 5 and FIG. 6 together with FIG. 3 and FIG. 4, in each pixel region PX of the image sensor 10, the active region 118, the photoelectric conversion portion 120, and the pixel circuit 130 will be described in more detail.

FIG. 5 is a plan view that illustrates an example pixel region PX among the plurality of pixel regions PX of the image sensor 10 illustrated in FIG. 4. FIG. 6 is an example cross-sectional view taken along a line C-C’ in FIG. 5. For a clear understanding, FIG. 5 illustrates the first pixel region PX1 illustrated in FIG. 4 and the below description is based on the first pixel region PX1. Unless otherwise described, the description of the first pixel region PX1 may be applied to the second pixel region PX2, the third pixel region PX3, and/or the fourth pixel region PX4. For a clear understanding, in FIG. 5, for second or third transistor 144 or 146, a portion where a gate electrode 140g is disposed is illustrated. For a clear understanding, in FIG. 6, for a first transistor 142, a portion where a transfer gate electrode 142g is disposed is illustrated.

Referring to FIG. 3 to FIG. 6, each pixel region PX may include a first portion P1 and a second portion P2. In the first direction (the X-axis direction in the drawings), the first portion P1 may be disposed at a first side S1 (e.g., a left side), and the second portion P2 may be disposed at a second side S2 (e.g., a right side).

In FIG. 5, it is illustrated as an example that, in each pixel region PX, the first portion P1 and the second portion P2 are adjacent to each other in the first direction (the X-axis direction in the drawings), and each of the first portion P1 and the second portion P2 has a shape (e.g., a vertical extension shape) that extends in the second direction (the Y-axis direction in the drawings). For example, in a plan view, the first portion P1 may be defined by a pair of first extension portions 128a, one second extension portion 128b, the first inner portion 128c, and the second inner portion 128d, and the second portion P2 may be defined by a pair of first extension portions 128a, another second extension portion 128b, the first inner portion 128c, and the second inner portion 128d.

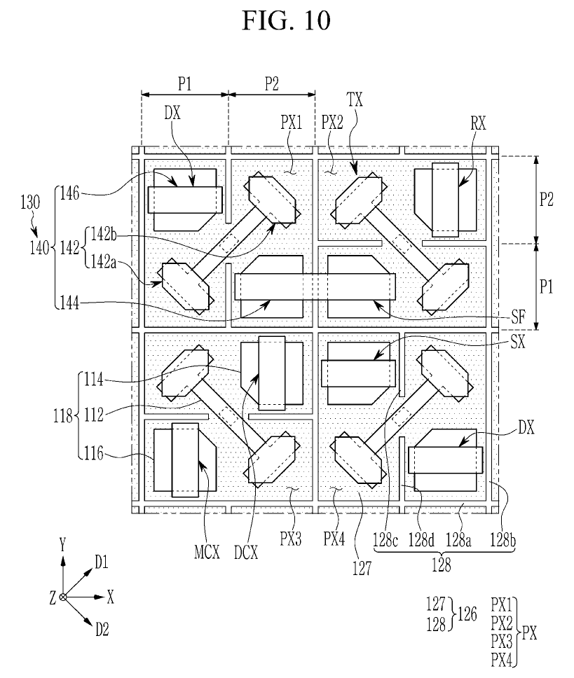

However, the implementations are not limited thereto, and a number, an arrangement, or the like of the first portion P1 and the second portion P2 that are included in each pixel region PX, and a number, an arrangement, or the like of the first inner portion 128c and the second inner portion 128d may be variously modified. In some implementations, in each pixel region PX, the first portion P1 and the second portion P2 may be adjacent to each other in the second direction (the Y-axis direction in the drawings), and each of the first portion P1 and the second portion P2 may have a shape (e.g., a horizontal extension shape) that extends in the first direction (the X-axis direction in the drawings). In some implementations, in at least one of the plurality of pixel regions PX, the first portion P1 and the second portion P2 may be adjacent to each other in the first direction, and each the first portion P1 and the second portion P2 may have a shape (e.g., a vertical extension shape) that extends in the second direction. In another one of the plurality of pixel regions PX, the first portion P1 and the second portion P2 may be adjacent to each other in the second direction, and each the first portion P1 and the second portion P2 may have a shape (e.g., a horizontal extension shape) that extends in the first direction. This will be described in more detail with reference to FIG. 10 to FIG. 12.

In some implementations, in each pixel region PX, the photoelectric conversion portion 120 (e.g., the first conductivity type region 122) may include a plurality of conversion portions. In some implementations, in each of the first portion P1 and the second portion P2, a conversion portion of the photoelectric conversion portion 120 (e.g., the first conductivity type region 122) may be disposed. For example, a first conversion portion 122a of the first conductivity type region 122 may be disposed in the first portion P1, and a second conversion portion 122b of the first conductivity type region 122 may be disposed in the second portion P2. Accordingly, in each pixel region PX, the first conversion portion 122a may be disposed at the first side S1 (e.g., the left side) in the first direction (the X-axis direction in the drawings), and the second conversion portion 122b may be disposed at the second side S2 (e.g., the right side) in the first direction. A connection portion 122d of the first conductivity type region 122 may be further included. The connection portion 122d of the first conductivity type region 122 may connect the first conversion portion 122a and the second conversion portion 122b between the first inner portion 128c and the second inner portion 128d.

In FIG. 5, it is illustrated as an example that the first conversion portion 122a and the second conversion portion 122b are adjacent to each other in the first direction (the X-axis direction in the drawings), and each of the first conversion portion 122a and the second conversion portion 122b has a shape (e.g., a vertical extension shape) that extends in the second direction (the Y-axis direction in the drawings). However, the implementations are not limited thereto. Therefore, a number, an arrangement, or the like of the conversion portion that is included in the first conductivity type region 122 may be variously modified.

In each pixel region PX, by using a difference between a signal from the first conversion portion 122a and a signal from the second conversion portion 122b, an auto focusing (AF) property that automatically adjusts focus of the image sensor 10 may be improved.

The active region 118 of the substrate 110 may be defined by the first isolation portion of the isolation pattern 126 or the first isolation pattern 127 that is disposed to be adjacent to the first surface 110a of the substrate 110. The active region 118 may be a portion where the transistor 140 and/or the doping region is disposed. The transistor 140 may include a first transistor 142, a second transistor 144, and a third transistor 146.

In each pixel region PX, the active region 118 may include a first active region 112 where the first transistor 142 is disposed. In each pixel region PX, the active region 118 may include a second active region 114 where the second transistor 144 is disposed and a third active region 116 where the third transistor 146 is be disposed. The first transistor 142 may include a transfer transistor TX, and the floating diffusion region 120f may be disposed in the first active region 112. The second transistor 144 or the third transistor 146 may include a reset transistor RX, a first gain control transistor DCX, a second gain control transistor MCX, a selection transistor SX, a driving transistor SF, a dummy transistor, or the like.

The first transistor 142 may include a transfer gate electrode 142g. The transfer gate electrode 142g may be a vertical transfer gate (VTG) electrode. The transfer gate electrode 142g or the vertical transfer gate electrode may have a cross-sectional shape in which a length (e.g., a maximum length) in a thickness direction (the Z-axis direction in the drawings) of the image sensor 10 is greater than a width (e.g., a minimum width in the X-axis or Y-axis direction in the drawings) in a plan view. The first transistor 142 may further include a transfer gate insulation layer 142i that is disposed between the transfer gate electrode 142g and the substrate 110. In some implementations, the first transistor 142 may include a first transfer transistor 142a and a second transfer transistor 142b. The first transfer transistor 142a may be electrically connected to the first conversion portion 122a, and the second transfer transistor 142b may be electrically connected to the second conversion portion 122b.

The second transistor 144 or the third transistor 146 may have a structure, a shape, or a depth different from a structure, a shape, or a depth of the first transistor 142. Having a different structure, shape, or depth may refer to that an electrode, a layer, or a doped portion that is included in or related to one of the first and second transistors 142 and 144 is not included in or related to another one of the first and second transistors 142 and 144. Having a different structure or shape may refer to that a position, an arrangement, or the like of electrodes, layers, or doped portions that are included in or related to the first and second transistors 142 and 144 are different. Having a different structure or shape may refer to that cross-sectional structures or shapes of electrodes, layers, or doped portions that are included in or related to the first and second transistors 142 and 144 are different. Having a different depth may refer to that depths of electrodes, layers, or doped portions that are included in or related to the first and second transistors 142 and 144 are different or depths of the first and second transistors 142 and 144 are different. Having a different structure, shape, or depth may refer to that an electrode, a layer, or a doped portion that is included in or related to one of the first and third transistors 142 and 146 is not included in or related to another one of the first and third transistors 142 and 146. Having a different structure or shape may refer to that a position, an arrangement, or the like of electrodes, layers, or doped portions that are included in or related to the first and third transistors 142 and 146 are different. Having a different structure or shape may refer to that cross-sectional structures or shapes of electrodes, layers, or doped portions that are included in or related to the first and third transistors 142 and 146 are different. Having a different depth may refer to that depths of electrodes, layers, or doped portions that are included in or related to the first and third transistors 142 and 146 are different or depths of the first and third transistors 142 and 146 are different. That is, even when there is a difference in width or length in a plan view, planar shape, or the like, transistors may be regarded to have a same structure or shape. For example, the second transistor 144 or the third transistor 146 may have a cross-sectional structure different from a cross-sectional structure of the first transistor 142.

In some implementations, the second transistor 144 or the third transistor 146 may have a planar structure. For example, the second transistor 144 or the third transistor 146 may include a gate insulation layer 140i, a gate electrode 140g, spacers 140p, a source region 140s, and a drain region 140d. The gate insulation layer 140i and the gate electrode 140g may be sequentially disposed on the substrate 110. The spacers 140p may be disposed at opposite sides of the gate insulation layer 140i and the gate electrode 140g. The source region 140s and the drain region 140d may be disposed in portions of the substrate 110 outside the gate electrode 140g and the spacers 140p. The gate insulation layer 140i and the gate electrode 140g may have a shape that extends in a plan view on the first surface 110a of the substrate 110.

In some implementations, the first active region 112 may include a first active portion 112a, a second active portion 112b, and a connection active portion 112c. In the first active portion 112a, the first transfer transistor 142a may be disposed. In the second active portion 112b, the second transfer transistor 142b may be disposed. The connection active portion 112c may connect the first active portion 112a and the second active portion 112b.

In some implementations, the connection active portion 112c may have a line shape that longitudinally extends in a direction. The first and second active portions 112a and 112b may be disposed at opposite sides, respectively, in a direction (e.g., a first diagonal direction D1) that is inclined to the first direction (the X-axis direction in the drawings) and the second direction (the Y-axis direction in the drawings). The connection active portion 112c may extend in the direction (e.g., the first diagonal direction D1) that is inclined to the first direction (the X-axis direction in the drawings) and the second direction (the Y-axis direction in the drawings) and connect the first active portion 112a and the second active portion 112b. For example, the first active region 112 or the connection active portion 112c may extend from one side of the separation portion SP (e.g., the first portion P1 or the first conversion portion 122a) to the other side of the separation portion SP (e.g., the second portion P2 or the second conversion portion 122b) along the first diagonal direction D1.

The first diagonal direction D1 may refer to a direction that is inclined to at least a portion of the second isolation pattern 128. For example, the first diagonal direction D1 may have an acute angle (an angle greater than 0 degrees and less than 90 degrees) with respect to an extension direction of the first extension portion 128a, may have an acute angle with respect to an extension direction of the second extension portion 128b, or may have an acute angle with respect to the first or second inner portion 128c or 128d. That is, the extension direction of the first active region 112 or the connection active portion 112c may have an acute angle with respect to the extension direction of the first extension portion 128a, may have an acute angle with respect to an the extension direction of the second extension portion 128b, or may have an acute angle with respect to the extension direction of the first or second inner portion 128c or 128d. In some implementations, the extension direction of the first active region 112 or the connection active portion 112c may have an angle of 30 to 60 degrees with respect to the extension direction of the first extension portion 128a, may have an angle of 30 to 60 degrees with respect to the extension direction of the second extension portion 128b, or may have an angle of 30 to 60 degrees with respect to the first or second inner portion 128c or 128d. However, the implementations are not limited thereto. By a size, a ratio, an arrangement, a process error, or the like of the pixel region PX, an angle between the extension direction of the first or second extension portion 128a or 128b and the connection active portion 112c or an angle between the extension direction of the first or second inner portion 128c or 128d and the connection active portion 112c may be less than 30 degrees or greater than 60 degrees.

In some implementations, the connection active portion 112c may extend in one extension direction and may not include a bent portion, a curved portion, a folded portion, or the like, but the implementations are not limited thereto. In some implementations, an imaginary straight line that connects from one side of the first active region 112 (e.g., the connection active portion 112c) to the other side of the first active region 112 (e.g., the connection active portion 112c) may extend in the first diagonal direction D1. In this instance, at least a portion of the connection active portion 112c may include a bent portion, a curved portion, a folded portion, or the like. That is, the connection active portion 112c may have any of various structures in which one side of the connection active portion 112c is adjacent to a third side S3 in the first portion P1 and the other side of the connection active portion 112c is adjacent to a fourth side S4 in the second portion P2.

The first active portion 112a and the second active portion 112b may be symmetrical to each other in the first diagonal direction D1 where the connection active portion 112c extends. In the specification, the phrase that two portions are symmetrical to each other in a direction may refer to that the two portions are line-symmetrical to each other with respect to a perpendicular direction that is perpendicular to the direction. That is, the phrase that two portion are symmetrical to each other in the first diagonal direction D1 may refer to that the two portion are line-symmetrical to each other with respect to a perpendicular direction (e.g., a second diagonal direction D2) that is perpendicular to the first diagonal direction D1.

In some implementations, the first active region 112 may have a point-symmetrical shape in the pixel region PX. For example, in a plan view, the first active portion 112a and the second active portion 112b may have a point-symmetrical shape in the pixel region PX. The phrase that two regions, two portions, or two arrangements have a point-symmetrical shape in the pixel region PX may refer to that the two regions, the two portions, or the two arrangements have a point-symmetrical shape with respect to a center of the pixel region PX. That is, the phrase that two regions, two portions, or two arrangements have a point-symmetrical shape in the pixel region PX may refer to that the two regions, the two portions, or the two arrangements have shapes that are rotated 180 degrees with respect to the center of the pixel region PX.

In some implementations, the first active portion 112a may extend in a direction that intersects (e.g., is perpendicular to) the connection active portion 112c, and the second active portion 112b may extend in a direction that intersects (e.g., is perpendicular to) the connection active portion 112c. For example, the first active portion 112a and the second active portion 112b may extend in the second diagonal direction D2 that intersects (e.g., is perpendicular to) the first diagonal direction D1, and the first active portion 112a and the second active portion 112b may be parallel to each other. For example, the first active portion 112a may have first and second edges that extend in the second diagonal direction D2 and third and fourth edges that extend in the first diagonal direction D1. For example, the second active portion 112b may have first and second edges that extend in the second diagonal direction D2 and third and fourth edges that extend in the first diagonal direction D1. The first to fourth edges of the first active portion 112a may have a point-symmetrical shape with the first to fourth edges of the second active portion 112b in the pixel region PX. The first active portion 112a and the second active portion 112b may have a substantially same planar area. The substantially same planar area may include a case where there is a difference within a process error (e.g., within 10%).

In some implementations, a width of the first active portion 112a may be greater than a width of the connection active portion 112c, and a width of the second active portion 112b may be greater than the width of the connection active portion 112c. The width of the first active portion 112a or the width of the second active portion 112b may refer to a width in a direction (e.g., the second diagonal direction D2) that is perpendicular to the extension direction of the connection active portion 112c (e.g., the first diagonal direction D1), for example, a maximum width. The width of the connection active portion 112c may refer to a width in a direction that is perpendicular to the extension direction of the connection active portion 112c, for example, a minimum width.

The first transfer transistor 142a that is disposed at the first active portion 112a may have a dual vertical transfer gate (dual VTG) structure, and the second transfer transistor 142b that is disposed at the second active portion 112b may have a dual vertical transfer gate structure. That is, the first transfer transistor 142a may include two gate electrode portions 142h that extend inside the substrate 110, respectively, and the second transfer transistor 142b may include two gate electrode portions 142h that extend inside the substrate 110, respectively. The two gate electrode portions 142h that are included in the first transfer transistor 142a or the second transfer transistor 142b may disposed at opposite sides in the extension direction of the first active portion 112a or the second active portion 112b (e.g., the second diagonal direction D2).

When the first or second transfer transistor 142a or 142b has the dual vertical transfer gate structure, the charges generated in the photoelectric conversion portion 120 may be effectively transferred by the transfer transistor TX. In FIG. 5, it is illustrated as an example that the two gate electrode portions 142h that are disposed at one first active portion 112a are spaced apart from each other in the substrate 110, and portions of the two gate electrode portions 142h that are adjacent to the first surface 110a of the substrate 110 are connected to each other. However, the implementations are not limited thereto. In some implementations, the two gate electrode portions 142h that are disposed at one first active portion 112a may be spaced apart from each other. In some implementations, the first transfer transistor 142a and/or the first transfer transistor 142a may have a single vertical transfer gate (single VTG) structure. Other various modifications are possible.

In second diagonal direction D2 that intersects the first diagonal direction D1, the second active region 114 may be disposed at one side of the first active region 112, and the third active region 116 may be disposed at the other side of the first active region 112. For example, the second active region 114 and the third active region 116 may be disposed to be symmetrical to each other in the second diagonal direction D2. That is, the second active region 114 and the third active region 116 may be line-symmetrical to each other with respect to a direction (e.g., the first diagonal direction D1) that is perpendicular to the second diagonal direction D2. The second active region 114 and the third active region 116 may have a point-symmetrical shape in the pixel region PX.

The second active region 114 may have first and second edges that extend in the first direction (the X-axis direction in the drawings), third and fourth edges that extend in the second direction (the Y-axis direction in the drawings), and a fifth edge that faces the first active region 112 and extends in a direction (e.g., the first diagonal direction D1) inclined to the first to fourth edges. The third active region 116 may have first and second edges that extend in the first direction, third and fourth edges that extend in the second direction, and a fifth edge that faces the first active region 112 and extends in a direction (e.g., the first diagonal direction D1) inclined to the first to fourth edges. The first to fifth edges of the second active region 114 may have a point-symmetrical shape with the first to fifth edges of the third active region 116 in the pixel region PX. The second active region 114 and the third active region 116 may have a substantially same planar area.

In FIG. 5, it is illustrated as an example that the gate electrode 140g of the second or third transistor 144 or 146 extends in the first direction (the X-axis direction in the drawings) that intersects (e.g., is perpendicular to) the extension direction of the first or second inner portion 128c or 128d. Thereby, an interval between the plurality of transistors 140 may increase and a structure or a density of the wiring portion 170 may be improved. However, the implementations are not limited thereto, and the gate electrode 140g of the second or third transistor 144 or 146 may extend in the second direction (the Y-axis direction in the drawings).

In some implementations, the first transistor 142, the second transistor 144, and the third transistor 146 are provided in each pixel region PX, and the second transistors 144 and the third transistors 146 that perform different operations may be shared in the plurality of pixel regions PX constituting one unit pixel group.

The floating diffusion region 120f may be disposed in a portion of the first active region 112 disposed between the first inner portion 128c and the second inner portion 128d (e.g., the separation portion SP or a center portion of the pixel region PX). For example, in a plan view, the floating diffusion region 120f may be disposed in a center portion of the connection active portion 112c. In a plan view, the first active portion 112a and the second active portion 112b may have a point-symmetrical shape with respect to the floating diffusion region 120f. That is, in a plan view, the first active portion 112a may have a shape in which the second active portion 112b is rotated 180 degrees with respect to the floating diffusion region 120f.

In a plan view, the first inner portion 128c and the first active region 112 may have a point-symmetrical shape with the second inner portion 128d and the first active region 112.

In a plan view, an arrangement of the first inner portion 128c and the first active region 112 may have a point-symmetrical shape with an arrangement of the second inner portion 128d and the first active region 112 in the pixel region PX. For example, in a plan view, an arrangement of the first inner portion 128c and the first active portion 112a may have a point-symmetrical shape with an arrangement of the second inner portion 128d and the second active portion 112b in the pixel region PX. For example, in a plan view, an arrangement of the first inner portion 128c and a portion of the connection active portion 112c that is adjacent to the first inner portion 128c may have a point-symmetrical shape with an arrangement of the second inner portion 128d and a portion of the connection active portion 112c that is adjacent to the second inner portion 128d in the pixel region PX.

In a plan view, an arrangement of the first inner portion 128c and the first active region 112 may have a point-symmetrical shape with an arrangement of the second inner portion 128d and the first active region 112 with respect to the floating diffusion region 120f. For example, in a plan view, an arrangement of the first inner portion 128c and the first active portion 112a may have a point-symmetrical shape with an arrangement of the second inner portion 128d and the second active portion 112b with respect to the floating diffusion region 120f. For example, in a plan view, an arrangement of the first inner portion 128c and a portion of the connection active portion 112c that is adjacent to the first inner portion 128c may have a point-symmetrical shape with an arrangement of the second inner portion 128d and a portion of the connection active portion 112c that is adjacent to the second inner portion 128d with respect to the floating diffusion region 120f.

In some implementations, in a plan view, in each pixel region PX, the first transfer transistor 142a may be disposed at a portion (e.g., a first transfer transistor portion) to overlap the first conversion portion 122a disposed at the first side S1 in the first direction (the X-axis direction in the drawings) and may be disposed at the third side S3 in the second direction (the Y-axis direction in the drawings) that intersects the first direction. In a plan view, in each pixel region PX, the second transfer transistor 142b may be disposed at a portion (e.g., a second transfer transistor portion) to overlap the second conversion portion 122b disposed at the second side S2 in the first direction and may be disposed at the fourth side S4 in the second direction that is opposite to the third side S3. In a plan view, in each pixel region PX, the third transistor 146 may be disposed to overlap the first conversion portion 122a and may be disposed at the fourth side S4 in the second direction. In a plan view, in each pixel region PX, the second transistor 144 may be disposed to overlap the second conversion portion 122b and may be disposed at the third side S3 in the second direction.

Accordingly, with respect to a center region of the pixel region PX, the first transfer transistor 142a and the second transfer transistor 142b may be disposed at opposite sides in the first diagonal direction D1, respectively. With respect to the center region of the pixel region PX, the second transistor 144 and the third transistor 146 may be disposed at opposite sides in the second diagonal direction D2, respectively. That is, the second transistor 144 may be disposed at one side of the first active region 112 in the second diagonal direction D2, and the third transistor 146 may be disposed at the other side of the first active region 112 in the second diagonal direction D2.

The first transfer transistor 142a and the second transistor 144 may be disposed at opposite sides of the first inner portion 128c while interposing the first inner portion 128c in the first direction (the X-axis direction in the drawings), and the second transfer transistor 142b and the third transistor 146 may be disposed at opposite sides of the second inner portion 128d while interposing the second inner portion 128d in the first direction.

In a plan view, the first transfer transistor 142a and the second transfer transistor 142b may have a point-symmetrical shape in the pixel region PX. In a plan view, the second transistor 144 and the third transistor 146 may have a point-symmetrical shape in the pixel region PX. Even in a case that the gate electrode 140g included in one of the second transistor 144 and the third transistors 146 extends to be shared in two adjacent pixel regions PX and the gate electrode 140g included in the other of the second transistor 144 and the third transistors 146 corresponds to one pixel region PX, when at least two (e.g., at least three, as an example, four) of the plurality of edges are symmetrical to each other or overlapping regions of the gate electrodes 140g and the active regions 118 are symmetrical to each other, the second transistor 144 and the third transistor 146 may be regarded as to have a point-symmetrical shape.

As in the above, in some implementations, in the pixel region PX, the first active region 112 may have a point-symmetrical shape, and the second active region 114 and the third active region 116 may have a point-symmetrical shape. In the pixel region PX, the first transfer transistor 142a and the second transfer transistor 142b may have a point-symmetrical shape, and the second transistor 144 and the third transistor 146 may have a point-symmetrical shape. That is, in the pixel region PX, the active region 118 or the pixel circuit 130 may have a point-symmetrical shape.

The active region 118 may have an asymmetrical shape in the first direction (the X-axis direction in the drawings) and/or the second direction (the Y-axis direction in the drawings). The phrase that a region, a portion, or the like has an asymmetrical shape in the first direction may refer to that the region, the portion, or the like is not line-symmetrical with respect to a perpendicular direction (e.g., the second direction) that is perpendicular to the first direction. The phrase that a region, a portion, or the like has an asymmetrical shape in the second direction may refer to that the region, the portion, or the like is not line-symmetrical with respect to a perpendicular direction (e.g., the first direction) that is perpendicular to the second direction. For example, the first active region 112 may have an asymmetrical shape in the first direction and/or the second direction. The second active region 114 and the third active region 116 may have an asymmetrical shape in the first direction and/or the second direction.

The pixel circuit 130 may have an asymmetrical shape in the first direction (the X-axis direction in the drawings) and/or the second direction (the Y-axis direction in the drawings). For example, the first transfer transistor 142a and the second transfer transistor 142b may have an asymmetrical shape in the first direction and/or the second direction. For example, the second transistor 144 and the third transistor 146 may have an asymmetrical shape in the first direction and/or the second direction.

In some implementations, the plurality of transistors 140 may be electrically connected to each other to constitute a desired circuit by the wiring layer 170 (e.g., a first wiring layer adjacent to the plurality of transistors 140).

Referring to FIG. 2, FIG. 4, and FIG. 5, an arrangement of the transistors 140 and the active region 118 in the plurality of pixel regions PX will be described in detail.

Referring to FIG. 2, FIG. 4, and FIG. 5, two pixel regions PX of the first to fourth pixel regions PX1, PX2, PX3, and PX4 may be symmetrical to each other or may have a same arrangement. More particularly, active regions 118 (e.g., first active regions 112, second active regions 114, and third active regions 116) in two pixel regions PX of the first to fourth pixel regions PX1, PX2, PX3, and PX4 may be symmetrical to each other or may have a same arrangement. Further, pixel circuits 130 in two pixel regions PX of the first to fourth pixel regions PX1, PX2, PX3, and PX4 may be symmetrical to each other or may have a same arrangement.

In the following description, for a clear understanding, in each pixel region PX, a transfer transistor TX adjacent to a center of a unit pixel group in the second direction (the Y-axis direction in the drawings) may be referred to as a first transfer transistor 142a, and a transfer transistor TX far away from the center of the unit pixel group in the second direction may be referred to as a second transfer transistor 142b. In each pixel region PX, among the second transistor 144 and the third transistor 146, a transistor adjacent to the center of the unit pixel group may be referred to as a second transistor 144, and a transistor far away from the center of the unit pixel group may be referred to as a third transistor 146.

In the first pixel region PX1, the first active region 112 may extend in the first diagonal direction D1, and the second active region 114 and the third active region 116 may be symmetrical to each other in the second diagonal direction D2. The first transfer transistor 142a and the second transfer transistor 142b may be symmetrical to each other in the first diagonal direction D1, and the second transistor 144 and the third transistor 146 may be symmetrical to each other in the second diagonal direction D2.

The second pixel region PX2 may be symmetrical with the first pixel region PX1 in the first direction (the X-axis direction in the drawings). That is, in the second pixel region PX2, the first active region 112 may extend in the second diagonal direction D2, and the second active region 114 and the third active region 116 may be symmetrical to each other in the first diagonal direction D1. The first transfer transistor 142a and the second transfer transistor 142b may be symmetrical to each other in the second diagonal direction D2, and the second transistor 144 and the third transistor 146 may be symmetrical to each other in the first diagonal direction D1.

The third pixel region PX3 may be symmetrical with the first pixel region PX1 in the second direction (the Y-axis direction in the drawings). The third pixel region PX3 and the second pixel region PX2 may have a same arrangement. That is, in the third pixel region PX3, the first active region 112 may extend in the second diagonal direction D2, and the second active region 114 and the third active region 116 may be symmetrical to each other in the first diagonal direction D1. The first transfer transistor 142a and the second transfer transistor 142b may be symmetrical to each other in the second diagonal direction D2, and the second transistor 144 and the third transistor 146 may be symmetrical to each other in the first diagonal direction D1.

The fourth pixel region PX4 may be symmetrical with the second pixel region PX2 in the second direction (the Y-axis direction in the drawings). The fourth pixel region PX4 and the first pixel region PX1 may have a same arrangement. That is, in the fourth pixel region PX4, the first active region 112 may extend in the first diagonal direction D1, and the second active region 114 and the third active region 116 may be symmetrical to each other in the second diagonal direction D2. The first transfer transistor 142a and the second transfer transistor 142b may be symmetrical to each other in the first diagonal direction D1, and the second transistor 144 and the third transistor 146 may be symmetrical to each other in the second diagonal direction D2.

The second transistor 144 in each pixel region PX (i.e., four second transistors 144 in the first to fourth pixel regions PX1, PX2, PX3, and PX4) may be the driving transistor SF. The gate electrode 140g may be shared in the second transistor 144 in the first pixel region PX1 and the second transistor 144 in the second pixel region PX2 to constitute a first driving transistor SF1. The gate electrode 140g may be shared in the second transistor 144 in the third pixel region PX3 and the second transistor 144 in the fourth pixel region PX4 to constitute a second driving transistor SF2. The first driving transistor SF1 and the second driving transistor SF2 may be connected in parallel.

As in the above, when the gate electrode 140g is shared in the second transistor 144 of the first pixel region PX1 and the second transistor 144 of the second pixel region PX2, when the gate electrode 140g is shared in the second transistor 144 of the third pixel region PX3 and the second transistor 144 of the fourth pixel region PX4, or when the first driving transistor SF1, which is included in at least one of the plurality of pixel regions PX, and the second driving transistor SF2, which is included in at least one of the plurality of pixel regions PX, are connected in parallel connected, a transistor width may increase and performance may be enhanced. The second transistors 144 in pixel regions PX configured to constitute the driving transistor SF may be adjacent to a center portion of the unit pixel group and a structure of the wiring portion 170 may be simplified.

The third transistor 146 in the first pixel region PX1 may be the selection transistor SX, and the third transistor 146 in the second pixel region PX2 may be the reset transistor RX, and the third transistor 146 in the third pixel region PX3 and the third transistor 146 in the fourth pixel region PX4 may be conversion gain transistors DCX and MCX, respectively.

However, the implementations are not limited to an arrangement of the second transistor 144 or the third transistor 146 in the first to fourth pixel regions PX1, PX2, PX3, and PX4.

According to some implementations, the first and second transfer transistors 142a and 142b may be disposed at opposite sides in the first diagonal direction D1 and the first active region 112 may extend in the first diagonal direction D1, and the first active region 112 may have a symmetrical shape (e.g., a point-symmetrical shape) with respect to the first or second inner portion 128c or 128d of the isolation pattern 126. Thereby, a problem that may be induced when a first active region has an asymmetrical shape with respect to the first and second inner portions 128c and 128d of the isolation pattern 126 may be prevented. Thereby, performance and productivity of the image sensor 10 may be enhanced.

For example, in a comparative example where an arrangement of a first active region and a first inner portion is asymmetrical to an arrangement of the first active region and a second inner portion in a second direction, a shape of an end of the first inner portion adjacent to the first active region may be different from a shape of an end of the second inner portion adjacent to the first active region. For example, when the first active region may have a V shape, the end of the first inner portion inside the V-shaped first active region may have a sharp shape, and the end of the second inner portion outside the V-shaped first active region may have a round shape. Accordingly, in the second direction, a distance between the first active region and the first inner portion may be different from a distance between the first active region and the second inner portion. For example, in the second direction, the distance between the first active region and the first inner portion may be less than the distance between the first active region and the second inner portion. Thereby, current leak may be induced or a defect may occur due to process dispersion. Thereby, performance or productivity of an image sensor may be deteriorated.

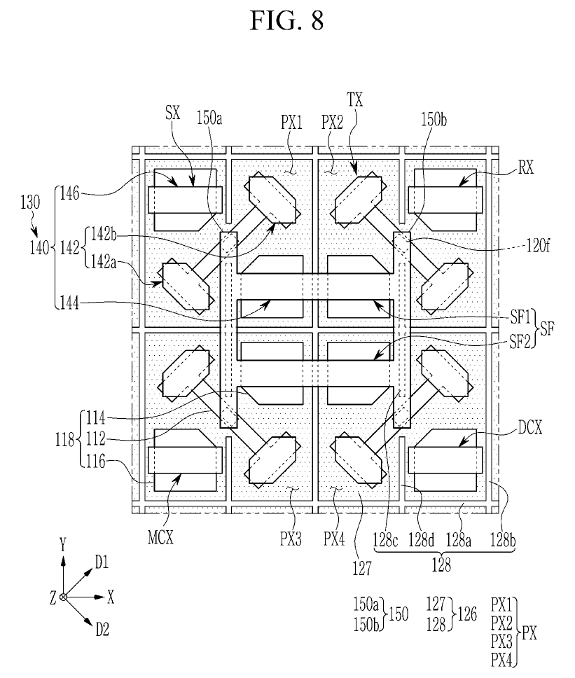

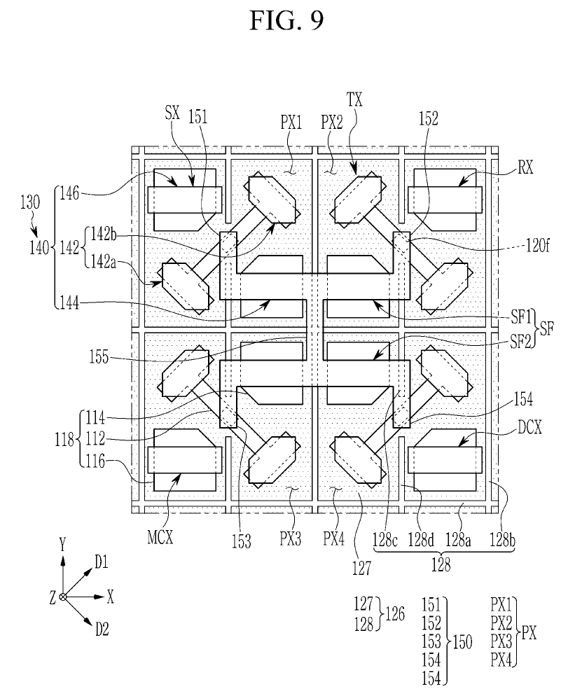

In some implementations, the second and third transistors 144 and 146 may be disposed at opposite sides in the second diagonal direction D2. Accordingly, freedom of a layout of the second and third transistors 144 and 146 and an area of the second and third transistors 144 and 146 may increase, and an interval between the plurality of transistors 140 may be secured. By securing an interval between the second transistor 144 and the third transistor 146, a space in which an additional wiring (e.g., a connection wiring 150) is disposed may be secured without changing the design of the transistors 140. The connection wiring 150 will be described later in detail with reference to FIG. 8 and FIG. 9.

The first transfer transistor 142a and the second transfer transistor 142b may share one floating diffusion region 120f, and may be spaced apart from the floating diffusion region 120f in the first diagonal direction D1. Since the first transfer transistor 142a and the second transfer transistor 142b may share one floating diffusion region 120f, a wiring length of the wiring portion 170 may be reduced and a conversion gain may be enhanced. Further, a distance between the first transfer transistor 142a and the floating diffusion region 120f and a distance between the second transfer transistor 142b and the floating diffusion region 120f may be sufficiently secured, and an electric property may be enhanced. For example, a gate induced drain leakage (GIDL) may be reduced.

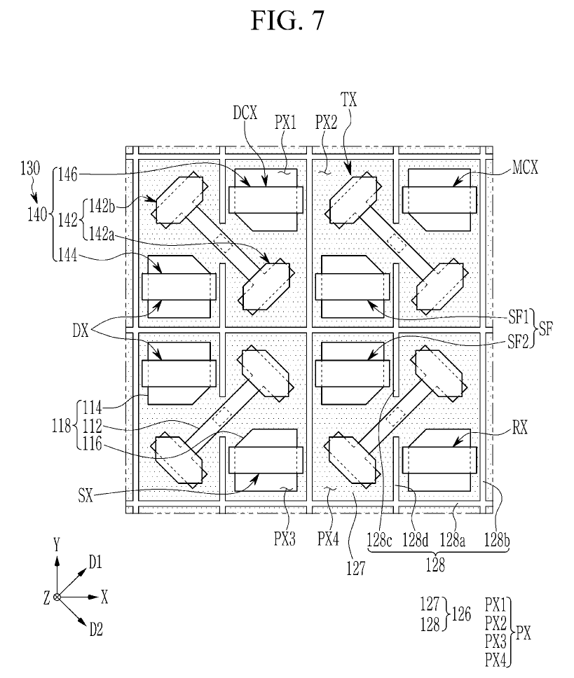

Hereinafter, with reference to FIG. 7 to FIG. 15, image sensors according to implementations will be described in more detail. To the extent that an element is not described in detail below, it may be understood that the element is at least substantially similar to a corresponding element that has been described elsewhere within the present disclosure. A portion which is not described in the above will be described in detail.

FIG. 7 is a plan view that schematically illustrates an example of a plurality of pixel regions PX of an image sensor. FIG. 7 illustrates a portion corresponding to FIG. 4. For second and third transistors 144 and 146, gate electrodes are mainly illustrated in FIG. 7.

Referring to FIG. 7, two pixel regions PX of first to fourth pixel regions PX1, PX2, PX3, and PX4 may be symmetrical to each other or may have a same arrangement. More particularly, active regions 118 (e.g., first active regions 112, second active regions 114, and third active regions 116) in two pixel regions PX of the first to fourth pixel regions PX1, PX2, PX3, and PX4 may be symmetrical to each other or may have a same arrangement. Further, pixel circuits 130 in two pixel regions PX of the first to fourth pixel regions PX1, PX2, PX3, and PX4 may be symmetrical to each other or may have a same arrangement.

In the following description, for a clear understanding, in each pixel region PX, a transfer transistor TX adjacent to a center of a unit pixel group in a second direction (a Y-axis direction in the drawings) may be referred to as a first transfer transistor 142a, and a transfer transistor TX far away from the center of the unit pixel group in the second direction may be referred to as a second transfer transistor 142b. In each pixel region PX, among a second transistor 144 and a third transistor 146, a transistor adjacent to a first side (a left side in the drawings) may be referred to as a second transistor 144, and a transistor adjacent to a second side (a right side in the drawings) may be referred to as a third transistor 146.

In a first pixel region PX1 or a second pixel region PX2, a first active region 112 may extend in a second diagonal direction D2, and a second active region 114 and a third active region 116 may be symmetrical to each other in a first diagonal direction D1. The first transfer transistor 142a and the second transfer transistor 142b may be symmetrical to each other in the second diagonal direction D2, and the second transistor 144 and the third transistor 146 may be symmetrical to each other in the first diagonal direction D1.

A third pixel region PX3 or a fourth pixel region PX4 may be symmetrical with the first pixel region PX1 or the second pixel region PX2 in the second direction (the Y-axis direction in the drawings). In the third pixel region PX3 or the fourth pixel region PX4, the first active region 112 may extend in the first diagonal direction D1, and the second active region 114 and the third active region 116 may be symmetrical to each other in the second diagonal direction D2. The first transfer transistor 142a and the second transfer transistor 142b may be symmetrical to each other in the first diagonal direction D1, and the second transistor 144 and the third transistor 146 may be symmetrical to each other in the second diagonal direction D2.

The second transistor 144 in each of the first pixel region PX1 and the third pixel region PX3 may be a dummy transistor DX. In some implementations, the dummy transistor DX may not perform function of a transistor and enhance a structural stability. In some implementations, the dummy transistor DX may perform any of various function.

The second transistor 144 in each of the second pixel region PX2 and the fourth pixel region PX4 may be a driving transistor SF. For example, the second transistor 144 in the second pixel region PX2 may be a first driving transistor SF1, and the second transistor 144 in the fourth pixel region PX4 may be a second driving transistor SF2. The first driving transistor SF1 and the second driving transistor SF2 may be connected in parallel. As in the above, when the first driving transistor SF1 and the second driving transistor SF2 are connected in parallel connected, a transistor width may increase and performance may be enhanced. The second transistors 144 in the second pixel region PX2 and the fourth pixel region PX4 configured to constitute the driving transistor SF may be adjacent to a center portion of the unit pixel group and a structure of a wiring portion may be simplified.

The third transistor 146 in the first pixel region PX1 and the third transistor 146 in the second pixel region PX2 may be conversion gain transistors DCX and MCX, respectively. The third transistor 146 in the third pixel region PX3 may be the selection transistor SX, and the third transistor 146 in the fourth pixel region PX4 may be the reset transistor RX.

However, the implementations are not limited to an arrangement of the second transistor 144 or the third transistor 146 in the first to fourth pixel regions PX1, PX2, PX3, and PX4.

According to some implementations, the first and third pixel regions PX1 and PX3 may have an arrangement same as an arrangement of the second and fourth pixel regions PX2 and PX4, and it may be advantageous in a manufacturing process. For example, a manufacturing process (e.g., a doping process, or the like) may be easily performed by using a mask of a same pattern.

In some implementations, the first to fourth pixel regions PX1, PX2, PX3, and PX4 may have a same arrangement. More particularly, the active regions 118 (e.g., the first active regions 112, the second active regions 114, and the third active regions 116) in the first to fourth pixel regions PX1, PX2, PX3, and PX4 may have a same arrangement. Further, the pixel circuits 130 in the first to fourth pixel regions PX1, PX2, PX3, and PX4 may have a same arrangement.

FIG. 8 is a plan view that schematically illustrates an example of a plurality of pixel regions PX of an image sensor. FIG. 8 illustrates a portion corresponding to FIG. 4. For second and third transistors 144 and 146, gate electrodes are mainly illustrated in FIG. 8.

Referring to FIG. 8, in some implementations, a pixel circuit 130 may include a connection wiring 150. The connection wiring 150 may extend from a gate electrode of a second transistor 144 (e.g., a driving transistor SF) in a plan view and may be electrically connected to a floating diffusion region 120f. For example, the connection wiring 150 may include or be formed of a same material (e.g., a polycrystalline semiconductor material) as the gate electrode of the second transistor 144 (e.g., the driving transistor SF) and extend from the gate electrode of the second transistor 144 (e.g., the driving transistor SF) in a plan view. The connection wiring 150 may be referred to as a poly local interconnector. In some implementations, the connection wiring 150 and the gate electrode of the second transistor 144 (e.g., the driving transistor SF) may be formed by a same process to have a single body. However, the implementations are not limited thereto.

In some implementations, the second transistor 144 and a third transistor 146 may be disposed at opposite sides in a second diagonal direction D2, and an interval between a plurality of transistors 140 may be secured. Therefore, a space where the connection wiring 150 is disposed may be sufficiently secured. In a comparative implementation where a second transistor and a third transistor are adjacent to each other in a first direction or a second direction, an interval between the second transistor and the third transistor is small and there is a difficulty in forming a connection wiring. For example, in the comparative example, in order to secure a space where the connection wiring is disposed, a design change of the second transistor and the third transistor is needed.

In some implementations, the connection wiring 150 may be in contact with a surface of the floating diffusion region 120f and be electrically connected to the floating diffusion region 120f. However, the implementations are not limited thereto, and a structure where the connection wiring 150 is electrically connected to the floating diffusion region 120f may be variously modified.

In some implementations, by the connection wiring 150, a contact via and a wiring portion that are electrically connected to the driving transistor SF may be reduced or omitted. Thereby, parasitic capacitance may be reduced, and a conversion gain may be enhanced and a noise may be reduced. However, the implementations are not limited thereto. In some implementations, a contact via and/or a wiring portion that is electrically connected to the driving transistor SF may be included.

In some implementations, the connection wiring 150 may include a first common connection wiring 150a and a second common connection wiring 150b. The first common connection wiring 150a may electrically connect a floating diffusion region 120f disposed in the first pixel region PX1, a floating diffusion region 120f disposed in the third pixel region PX3, one side of a gate electrode of the first driving transistor SF1, and one side of a gate electrode of the second driving transistor SF2. The second common connection wiring 150b may electrically connect a floating diffusion region 120f disposed in the second pixel region PX2, a floating diffusion region 120f disposed in the fourth pixel region PX4, the other side of the gate electrode of the first driving transistor SF1, and the other side of the gate electrode of the second driving transistor SF2.

Thereby, a structure of the first and second common connection wirings 150a and 150b may be simplified. However, the implementations are not limited thereto, and a shape, an arrangement, or the like of the first and second common connection wirings 150a and 150b may be variously modified.

In the above description, it is described as an example that the connection wiring 150 electrically connect the second transistor 144 and the floating diffusion region 120f. However, the implementations are not limited thereto, and the connection wiring 150 may include a portion that electrically connects a plurality of doping regions, a portion that electrically connects a doping region and the transistor 140, a portion that electrically connects the plurality of transistors 140, or the like. The connection wiring 150 may be spaced apart from the gate electrode of the second transistor 144.

Two pixel regions PX of the first to fourth pixel regions PX1, PX2, PX3, and PX4 may have a symmetrical arrangement or a same arrangement. In FIG. 8, it is illustrated as an example that the active regions 118 and the pixel circuit 130 in the first to fourth pixel regions PX1, PX2, PX3, and PX4 have an arrangement illustrated in FIG. 4, but the implementations are not limited thereto. In some implementations, the active regions 118 and the pixel circuits 130 may have an arrangement illustrated in FIG. 7. Other various modifications are possible.

FIG. 9 is a plan view that schematically illustrates an example of a plurality of pixel regions PX of an image sensor. FIG. 9 illustrates a portion corresponding to FIG. 4. For second and third transistors 144 and 146, gate electrodes are mainly illustrated in FIG. 9.

Referring to FIG. 9, in some implementations, a pixel circuit 130 may include a connection wiring 150. The connection wiring 150 may extend from a gate electrode of a second transistor 144 (e.g., a driving transistor SF) in a plan view and may be electrically connected to a floating diffusion region 120f. Unless otherwise described, a description of a connection wiring 150 with reference to FIG. 8 may be applied.

In some implementations, the connection wiring 150 may include first to fifth connection wirings 151, 152, 153, 154, and 155. The first connection wiring 151 may electrically connect a floating diffusion region 120f disposed in a first pixel region PX1 and one side of a gate electrode of a first driving transistor SF1. The second connection wiring 152 may electrically connect a floating diffusion region 120f disposed in a second pixel region PX2 and the other side of the gate electrode of the first driving transistor SF1. The third connection wiring 153 may electrically connect a floating diffusion region 120f disposed in a third pixel region PX3 and one side of a gate electrode of a second driving transistor SF2. The fourth connection wiring 154 may electrically connect the floating diffusion region 120f disposed in a fourth pixel region PX4 and the other side of the gate electrode of the second driving transistor SF2. The fifth connection wiring 155 may electrically connect the first driving transistor SF1 and the second driving transistor SF2. In FIG. 9, it is illustrated as an example that the fifth connection wiring 155 is disposed at a center in a first direction (an X-axis direction in the drawings), but the implementations are not limited thereto.

According to some implementations, the connection wiring 150 may be short and parasitic capacitance may be reduced.

FIG. 10 is a plan view that schematically illustrates an example of a plurality of pixel regions PX of an image sensor. FIG. 10 illustrates a portion corresponding to FIG. 4. For second and third transistors 144 and 146, gate electrodes are mainly illustrated in FIG. 10.

Referring to FIG. 10, in some implementations, a first or second inner portion 128c or 128d of an isolation pattern 126 may extend in a first direction (an X-axis direction in the drawings) in at least one of first to fourth pixel regions PX1, PX2, PX3, and PX4 (e.g., in a first one of a plurality of pixel regions PX), and a first or second inner portion 128c or 128d of the isolation pattern 126 may extend in a second direction (a Y-axis direction in the drawings) in at least another one of the first to fourth pixel regions PX1, PX2, PX3, and PX4 (e.g., in a second one of the plurality of pixel regions PX).

In some implementations, in the first to fourth pixel regions PX1, PX2, PX3, and PX4, active regions 118 may be disposed in a diagonal direction and a direction of the first or second inner portion 128c or 128d may be variously modified.

According to some implementations, an auto focusing property in the first direction (the X-axis direction in the drawings) may be enhanced in each of the first pixel region PX1 and the fourth pixel region PX4, and an auto focusing property in the second direction (the Y-axis direction in the drawings) may be enhanced in each of the second pixel region PX2 and the third pixel region PX3. Thereby, an auto focusing property may be effectively enhanced.

In FIG. 10, it is illustrated as an example that, in each of the first pixel region PX1 and the fourth pixel region PX4, a first portion P1 and a second portion P2 are adjacent to each other in the first direction (the X-axis direction in the drawings), and each of the first portion P1 and the second portion P2 has a shape (e.g., a vertical extension shape) that extends in the second direction (the Y-axis direction in the drawings). In each of the second pixel region PX2 and the third pixel region PX3, a first portion P1 and a second portion P2 are adjacent to each other in the second direction, and each of the first portion P1 and the second portion P2 has a shape (e.g., a horizontal extension shape) that extends in the first direction. However, the implementations are not limited thereto.

In some implementations, two pixel regions PX of the first to fourth pixel regions PX1, PX2, PX3, and PX4 may be symmetrical to each other or may have a same arrangement. More particularly, the active regions 118 (e.g., first active regions 112, second active regions 114, and third active regions 116) in two pixel regions PX of the first to fourth pixel regions PX1, PX2, PX3, and PX4 may be symmetrical to each other or may have a same arrangement. Further, pixel circuits 130 in two pixel regions PX of the first to fourth pixel regions PX1, PX2, PX3, and PX4 may be symmetrical to each other or may have a same arrangement.

In the following description, for a clear understanding, in each pixel region PX, a transfer transistor TX adjacent to a center of a unit pixel group in the second direction (the Y-axis direction in the drawings) may be referred to as a first transfer transistor 142a, and a transfer transistor TX far away from the center of the unit pixel group in the second direction may be referred to as a second transfer transistor 142b. In each pixel region PX, among a second transistor 144 and a third transistor 146, a transistor adjacent to the center of the unit pixel group may be referred to as a second transistor 144, and a transistor far away from the center of the unit pixel group may be referred to as a third transistor 146.

In the first pixel region PX1 or the fourth pixel region PX4, a first active region 112 may extend in a first diagonal direction D1, and a second active region 114 and a third active region 116 may be symmetrical to each other in a second diagonal direction D2. A first transfer transistor 142a and a second transfer transistor 142b may be symmetrical to each other in the first diagonal direction D1, and a second transistor 144 and a third transistor 146 may be symmetrical to each other in the second diagonal direction D2.

In the second pixel region PX2 or the third pixel region PX3, a first active region 112 may extend in the second diagonal direction D2, and a second active region 114 and a third active region 116 may be symmetrical to each other in the first diagonal direction D1. A first transfer transistor 142a and a second transfer transistor 142a may be symmetrical to each other in the second diagonal direction D2, and a second transistor 144 and a third transistor 146 may be symmetrical to each other in the first diagonal direction D1.

The second transistor 144 in the first pixel region PX1 and the second transistor 144 in the second pixel region PX2 may be the driving transistor SF. In the second transistor 144 in the first pixel region PX1 and the second transistor 144 in the second pixel region PX2, a gate electrode may be shared to constitute the driving transistor SF. The third transistor 146 in the first pixel region PX1 may be a dummy transistor DX, and the third transistor 146 in the second pixel region PX2 may be a reset transistor RX.

The second transistor 144 and the third transistor 146 in the third pixel region PX3 may be conversion gain transistors DCX and MCX, respectively. The second transistor 144 in the fourth pixel region PX4 may be a selection transistor SX, and the third transistor 146 in the fourth pixel region PX4 may be a dummy transistor DX.

However, the implementations are not limited to an arrangement of the second transistor 144 or the third transistor 146 in the first to fourth pixel regions PX1, PX2, PX3, and PX4.

In FIG. 10, it is illustrated as an example that the active regions 118 are symmetrical to each other in at least two pixel regions PX. However, the implementations are not limited thereto, and an arrangement of the active regions 118 included in the first to fourth pixel regions PX1, PX2, PX3, and PX4 may be variously modified.

In FIG. 10, it is illustrated as an example that the second transistors 144 in the first pixel region PX1 and the second pixel region PX2 extend in the first direction (the X-axis direction in the drawings). Thereby, the gate electrodes of the second transistors 144 in the first pixel region PX1 and the second pixel region PX2 may be shared by a simple structure. However, the implementations are not limited thereto, and at least one of the second transistors 144 in the first pixel region PX1 and the second pixel region PX2 may include a portion that extends in a direction other than the first direction.

In FIG. 10, it is illustrated as an example that the second transistors 144 in the third pixel region PX3 and the fourth pixel region PX4, and the third transistors 146 in the first to fourth pixel regions PX1, PX2, PX3, and PX4 extend in a direction that intersects (e.g., is perpendicular to) an extension direction of the first or second inner portion 128c or 128d. That is, the second transistor 144 in the fourth pixel region PX4, the third transistor 146 in the first pixel region PX1, and the third transistor 146 in the fourth pixel region PX4 may extend in the first direction (the X-axis direction in the drawings) that intersects (e.g., is perpendicular to) the second direction (the Y-axis direction in the drawings), which is the extension direction of the first or second inner portion 128c or 128d. The third transistor 146 in the second pixel region PX2, and the second and third transistors 144 and 146 in the third pixel region PX3 may extend in the second direction that intersects (e.g., is perpendicular to) the first direction, which is the extension direction of the first or second inner portion 128c or 128d.

Thereby, an interval between the plurality of transistors 140 may increase and a structure or a density of the wiring portion may be improved. However, the implementations are not limited thereto. Therefore, at least one of the second transistors 144 in the third pixel region PX3 and the fourth pixel region PX4, and the third transistors 146 in the first to fourth pixel regions PX1, PX2, PX3, and PX4 may extend in a direction parallel to the extension direction of the first or second inner portion 128c or 128d.

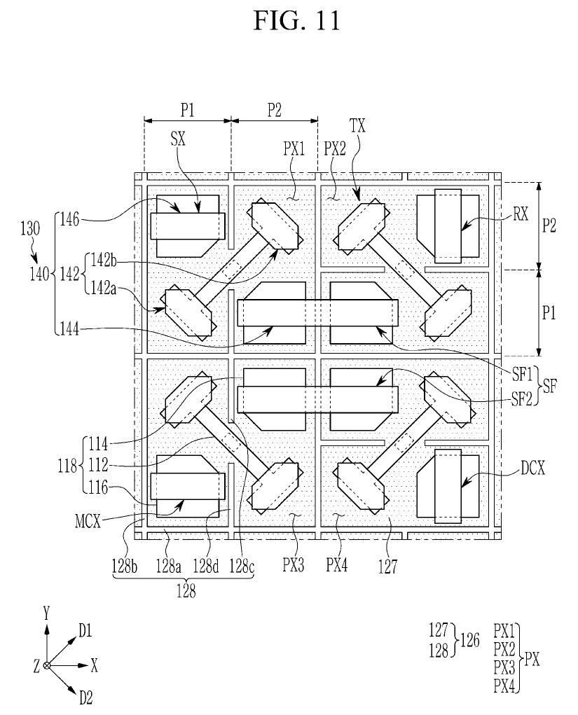

FIG. 11 is a plan view that schematically illustrates an example of a plurality of pixel regions PX of an image sensor. FIG. 11 illustrates a portion corresponding to FIG. 4. For second and third transistors 144 and 146, gate electrodes are mainly illustrated in FIG. 11.

Referring to FIG. 11, in some implementations, a first or second inner portion 128c or 128d of an isolation pattern 126 may extend in a first direction (the X-axis direction in the drawings) in at least one of first to fourth pixel regions PX1, PX2, PX3, and PX4, and a first or second inner portion 128c or 128d of the isolation pattern 126 may extend in a second direction (a Y-axis direction in the drawings) in at least another one of the first to fourth pixel regions PX1, PX2, PX3, and PX4. Thereby, an auto focusing property may be effectively enhanced. Unless otherwise described, a description with reference to FIG. 10 may be applied.

In the following description, for a clear understanding, in each pixel region PX, a transfer transistor TX adjacent to a center of a unit pixel group in the second direction (the Y-axis direction in the drawings) may be referred to as a first transfer transistor 142a, and a transfer transistor TX far away from the center of the unit pixel group in the second direction may be referred to as a second transfer transistor 142b. In each pixel region PX, among a second transistor 144 and a third transistor 146, a transistor adjacent to the center of the unit pixel group may be referred to as a second transistor 144, and a transistor far away from the center of the unit pixel group may be referred to as a third transistor 146.

In the first pixel region PX1 or the fourth pixel region PX4, a first active region 112 may extend in a first diagonal direction D1, and a second active region 114 and a third active region 116 may be symmetrical to each other in a second diagonal direction D2. A first transfer transistor 142a and a second transfer transistor 142b may be symmetrical to each other in the first diagonal direction D1, and a second transistor 144 and a third transistor 146 may be symmetrical to each other in the second diagonal direction D2.

In the second pixel region PX2 or the third pixel region PX3, a first active region 112 may extend in the second diagonal direction D2, and a second active region 114 and a third active region 116 may be symmetrical to each other in the first diagonal direction D1. A first transfer transistor 142a and a second transfer transistor 142b may be symmetrical to each other in the second diagonal direction D2, and a second transistor 144 and a third transistor 146 may be symmetrical to each other in the first diagonal direction D1.

The second transistor 144 in each pixel region PX (i.e., four second transistors 144 in the first to fourth pixel regions PX1, PX2, PX3, and PX4) may be a driving transistor SF. A gate electrode may be shared in the second transistor 144 in the first pixel region PX1 and the second transistor 144 in the second pixel region PX2 to constitute a first driving transistor SF1. A gate electrode may be shared in the second transistor 144 in the third pixel region PX3 and the second transistor 144 in the fourth pixel region PX4 to constitute a second driving transistor SF2. The first driving transistor SF1 and the second driving transistor SF2 may be connected in parallel. Thereby, a transistor width may increase and performance may be enhanced, and a structure of a wiring portion may be simplified.

The third transistor 146 in the first pixel region PX1 may be a selection transistor SX, and the third transistor 146 in the second pixel region PX2 may be a reset transistor RX, and the third transistor 146 in the third pixel region PX3 and the third transistor 146 in the fourth pixel region PX4 may be conversion gain transistors DCX and MCX, respectively.

However, the implementations are not limited to an arrangement of the second transistor 144 or the third transistor 146 in the first to fourth pixel regions PX1, PX2, PX3, and PX4.

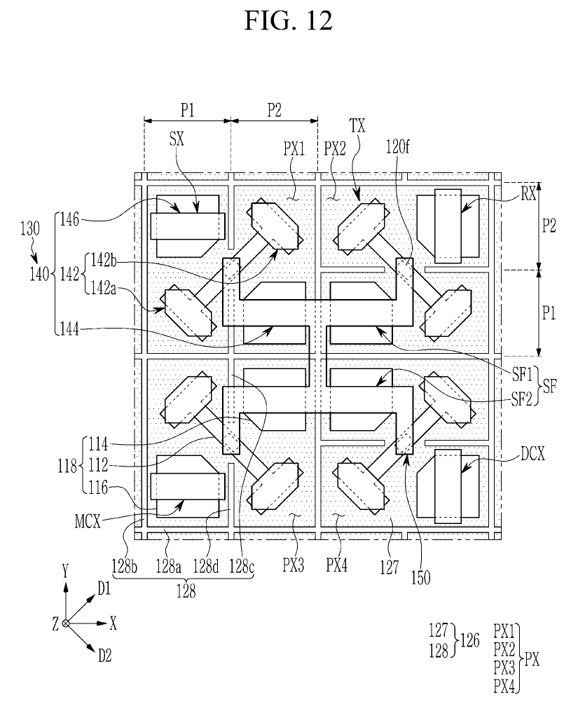

FIG. 12 is a plan view that schematically illustrates an example of a plurality of pixel regions PX of an image sensor. FIG. 12 illustrates a portion corresponding to FIG. 4. For second and third transistors 144 and 146, gate electrodes are mainly illustrated in FIG. 12.

Referring to FIG. 12, in some implementations, a first or second inner portion 128c or 128d of an isolation pattern 126 may extend in a first direction (a X-axis direction in the drawings) in at least one of first to fourth pixel regions PX1, PX2, PX3, and PX4, and a first or second inner portion 128c or 128d of the isolation pattern 126 may extend in a second direction (a Y-axis direction in the drawings) in at least another one of the first to fourth pixel regions PX1, PX2, PX3, and PX4. Thereby, an auto focusing property may be effectively enhanced. In FIG. 12, it is illustrated as an example that the first to fourth pixel regions PX1, PX2, PX3, and PX4 have an arrangement illustrated in FIG. 11. However, the implementations are not limited thereto, and the first to fourth pixel regions PX1, PX2, PX3, and PX4 may have an arrangement illustrated in FIG. 10. Other various modifications are possible.

In the following description, for a clear understanding, in each pixel region PX, a transfer transistor TX adjacent to a center of a unit pixel group in the second direction (the Y-axis direction in the drawings) may be referred to as a first transfer transistor 142a, and a transfer transistor TX far away from the center of the unit pixel group in the second direction may be referred to as a second transfer transistor 142b. In each pixel region PX, among a second transistor 144 and a third transistor 146, a transistor adjacent to the center of the unit pixel group may be referred to as a second transistor 144, and a transistor far away from the center of the unit pixel group may be referred to as a third transistor 146.

In some implementations, a connection wiring 150 may be included. The connection wiring 150 may extend from a gate electrode of a second transistor 144 (e.g., a driving transistor SF) in a plan view and may be electrically connected to a floating diffusion region 120f. Unless otherwise described, a description of a connection wiring 150 with reference to FIG. 8 and FIG. 9 may be applied.

In FIG. 12, it is illustrated as an example that the connection wiring 150 includes first to fifth connection wirings, as illustrated in FIG. 9. However, the implementations are not limited thereto, and the connection wiring 150 may include first and second common connection wirings, as illustrated in FIG. 8.

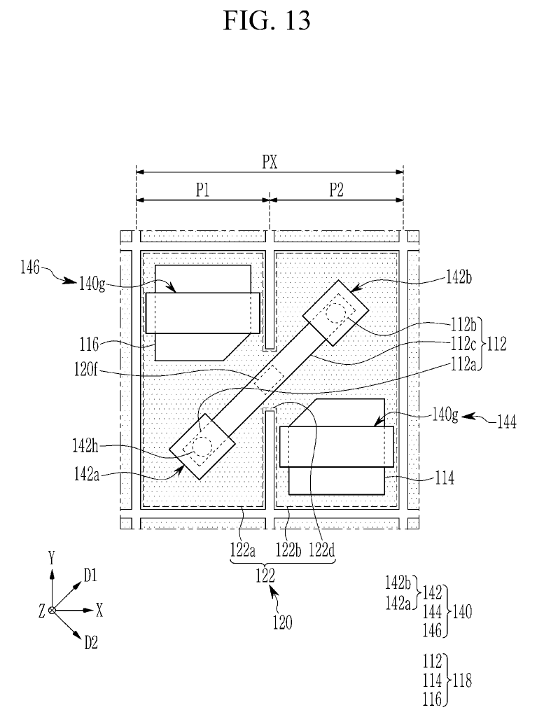

FIG. 13 is a plan view that schematically illustrates an example of a pixel region PX of an image sensor. FIG. 13 illustrates a portion corresponding to FIG. 5.

Referring to FIG. 13, in some implementations, a first active region 112 may have a uniform width in an entire portion. For example, a first active portion 112a, a second active portion 112b, and a connection active portion 112c may have a uniform width. First and second transfer transistors 142a and 142b may be disposed at opposite sides of the first active region 112 in a first diagonal direction D1. In some implementations, the first and second transfer transistors 142a and 142b may have a single vertical transfer gate structure.

In some implementations, since the first active region 112 where the first and second transfer transistors 142a and 142b are disposed has a uniform width, a distance or an interval between a plurality of active regions 118 or a distance or an interval between a plurality of transistors 140 may increase. Thereby, a noise may be reduced. A shape of the first active region 112 may be variously modified in consideration of an electron collection efficiency and a noise.

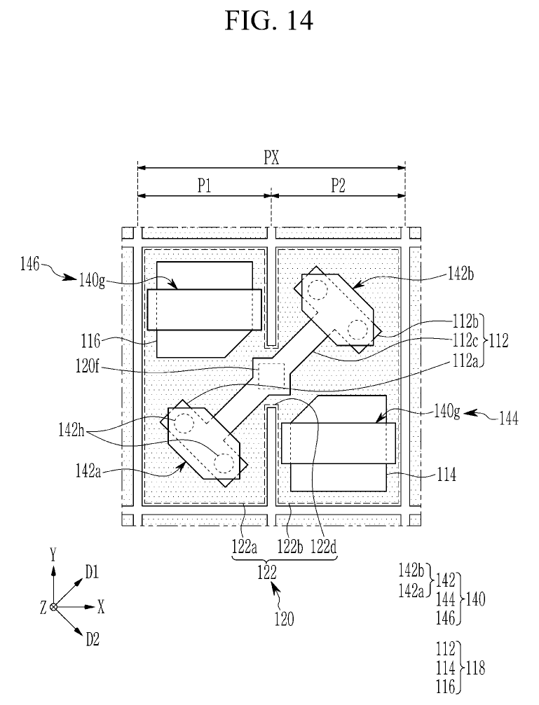

FIG. 14 is a plan view that schematically illustrates an example of a pixel region PX of an image sensor. FIG. 14 illustrates a portion corresponding to FIG. 5.

Referring to FIG. 14, in some implementations, a portion (e.g., a center portion) of a connection active portion 112c where a floating diffusion region 120f is disposed may have a width greater than a width of the other portion of the connection active portion 112c. Thereby, the floating diffusion region 120f may be stably formed. However, the implementations are not limited thereto, and various modifications are possible.

FIG. 15 is a partial cross-sectional view that illustrates an example of an image sensor. FIG. 15 illustrates a portion corresponding to FIG. 3.

Referring to FIG. 15, in an image sensor, an additional wiring portion 200 may include a first additional wiring portion 200a and a second additional wiring portion 200b that are disposed on a photoelectric conversion substrate 100. Thereby, the image sensor may have a multi-layered stacking structure (e.g., a three-layer stacking structure) that includes the photoelectric conversion substrate 100, and the first and second additional wiring portions 200a and 200b.

In FIG. 15, it is illustrated as an example that a wiring portion 170 and the first additional wiring portion 200a may be bonded by hybrid bonding including metal bonding and insulation-layer bonding, and the first additional wiring portion 200a includes a semiconductor substrate 210a, but the implementations are not limited thereto. In some implementations, the wiring portion 170 and the first additional wiring portion 200a may be bonded by insulation-layer bonding, and then, a connection member or the like configured to connect the wiring portion 170 and the first additional wiring portion 200a may be formed. The first additional wiring portion 200a and the second additional wiring portion 200b may be bonded by hybrid bonding including metal bonding and insulation-layer bonding, but the implementations are not limited thereto.

When the first and second additional wiring portions 200a and 200b are included as in the above, congestion of wirings, circuit elements, or the like that are included in the wiring portion 170 and the additional wiring portion 200 may be reduced. As a result, an area (e.g., a planar area) of a pixel region of an image sensor may be reduced and thus an integration degree and properties of the image sensor may be enhanced.

For example, the wiring portion 170 may include a wiring that is connected to the pixel circuit 130, the first additional wiring portion 200a may include a circuit element (e.g., a transistor), a wiring, or the like, and the second additional wiring portion 200b may include a logic circuit portion, a power supply portion, a wiring, or the like. However, the implementations are not limited thereto. A wiring, a circuit element, or the like included in the wiring portion 170, and the first and second additional wiring portions 200a and 200b may be variously modified. In some implementations, the image sensor may further include an additional wiring portion other than the first and second additional wiring portions 200a and 200b.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While some examples have been described in connection with some implementations, it is to be understood that the disclosure is not limited to the disclosed implementations, and that the disclosure is intended to cover various modifications and equivalent arrangements included within the spirit and scope of the appended claims.

What is claimed is:

1. An image sensor, comprising:
a substrate that has a first surface and a second surface opposite to each other;
a photoelectric conversion portion in the substrate;
a pixel circuit adjacent to the first surface of the substrate; and
an isolation pattern that extends through at least a portion of the substrate and includes an isolation portion, the isolation portion defining a region where the photoelectric conversion portion is disposed,
wherein the pixel circuit includes a first transistor,
wherein the first transistor includes a first transfer transistor and a second transfer transistor,
wherein the substrate includes an active region that is adjacent to the first surface of the substrate and includes a first active region, and
wherein the first active region includes a first active portion where the first transfer transistor is disposed, a second active portion where the second transfer transistor is disposed, and a connection active portion that connects the first active portion and the second active portion in a first diagonal direction inclined to the isolation portion.

2. The image sensor of claim 1, comprising:
a pixel region that includes the photoelectric conversion portion and the pixel circuit,
wherein the first active region or the pixel circuit has a point-symmetrical shape in the pixel region, and has an asymmetrical shape in an extension direction of the isolation portion.

3. The image sensor of claim 1, wherein the photoelectric conversion portion includes a first conversion portion and a second conversion portion,
wherein the first conversion portion is at a first side of the photoelectric conversion portion in a first direction inclined to the first diagonal direction,
wherein the second conversion portion is at a second side of the photoelectric conversion portion opposite to the first side in the first direction, and
wherein the first conversion portion and the second conversion portion extend in a second direction inclined to the first diagonal direction, and the second direction intersects the first direction.

4. The image sensor of claim 1, wherein the photoelectric conversion portion includes a first conversion portion and a second conversion portion,
wherein the first conversion portion is at a first side of the photoelectric conversion portion in a first direction inclined to the first diagonal direction,
wherein the second conversion portion is at a second side of the photoelectric conversion portion opposite to the first side in the first direction,
wherein, in a plan view, the first transfer transistor is at a first transfer transistor portion overlapping the first conversion portion and is at a third side of the photoelectric conversion portion in a second direction that intersects the first direction, and
wherein, in the plan view, the second transfer transistor is at a second transfer transistor portion overlapping the second conversion portion and is at a fourth side of the photoelectric conversion portion opposite to the third side in the second direction.

5. The image sensor of claim 1, wherein the connection active portion longitudinally extends in the first diagonal direction.

6. The image sensor of claim 1, comprising:
a floating diffusion region at a center portion of the connection active portion in a plan view,
wherein, in the plan view, the first active portion and the second active portion have a point-symmetrical shape with respect to the floating diffusion region.

7. The image sensor of claim 1, wherein each active portion of the first active portion and the second active portion has a width greater than a width of the connection active portion, and
wherein each transfer transistor of the first transfer transistor and the second transfer transistor has a dual vertical transfer gate (dual VTG) structure.

8. The image sensor of claim 1, wherein the pixel circuit includes a second transistor and a third transistor,
wherein each transistor of the second transistor and the third transistor has a cross-sectional shape different from a cross-sectional shape of the first transistor, and
wherein the second transistor is at a first side of the first active region in a second diagonal direction that intersects the first diagonal direction, and the third transistor is at a second side of the first active region in the second diagonal direction.

9. The image sensor of claim 1, wherein the pixel circuit includes a second transistor and a third transistor,
wherein each transistor of the second transistor and the third transistor has a cross-sectional shape different from a cross-sectional shape of the first transistor,
wherein the active region includes a second active region where the second transistor is disposed and a third active region where the third transistor is disposed, and
wherein the second active region is at a first side of the first active region in a second diagonal direction that intersects the first diagonal direction, and the third active region is at a second side of the first active region in the second diagonal direction.

10. The image sensor of claim 1, wherein the photoelectric conversion portion includes a first conversion portion and a second conversion portion,
wherein the first conversion portion is at a first side of the photoelectric conversion portion in a first direction inclined to the first diagonal direction,
wherein the second conversion portion is at a second side of the photoelectric conversion portion opposite to the first side in the first direction,
wherein the isolation pattern includes a first inner portion and a second inner portion that extend between the first conversion portion and the second conversion portion and are spaced apart from each other,
wherein the pixel circuit includes a second transistor and a third transistor,
wherein each transistor of the second transistor and the third transistor has a cross-sectional shape different from a cross-sectional shape of the first transistor,
wherein the first transfer transistor and the second transfer transistor are at two opposite sides of the first inner portion, the first inner portion being interposed in the first direction, and
wherein the second transfer transistor and the third transistor are at two opposite sides of the second inner portion, the second inner portion being interposed in the first direction.

11. The image sensor of claim 1, wherein the photoelectric conversion portion includes a first conversion portion and a second conversion portion,
wherein the first conversion portion is at a first side of the photoelectric conversion portion in a first direction inclined to the first diagonal direction,
wherein the second conversion portion is at a second side of the photoelectric conversion portion opposite to the first side in the first direction,
wherein the isolation pattern includes a first inner portion and a second inner portion that extend between the first conversion portion and the second conversion portion and are spaced apart from each other, and
wherein, in a plan view, the first inner portion and the first active portion have a point-symmetrical arrangement with the second inner portion and the second active portion.

12. The image sensor of claim 1, comprising:
a plurality of pixel regions,
wherein the plurality of pixel regions include:
a first pixel region and a second pixel region adjacent to each other in a first direction inclined to the first diagonal direction; and
a third pixel region and a fourth pixel region adjacent to the first pixel region and the second pixel region, respectively, in a second direction that intersects the first direction, and
wherein a plurality of first active regions in two pixel regions of the first pixel region, the second pixel region, the third pixel region, and the fourth pixel region have a symmetrical arrangement or a same arrangement.

13. The image sensor of claim 1, comprising:
a plurality of pixel regions,
wherein the plurality of pixel regions include:
a first pixel region and a second pixel region adjacent to each other in a first direction inclined to the first diagonal direction; and
a third pixel region and a fourth pixel region adjacent to the first pixel region and the second pixel region, respectively, in a second direction that intersects the first direction,
wherein the isolation pattern includes a first inner portion and a second inner portion that extend inside at least in a first one and a second one of the plurality of pixel regions and are spaced apart from each other, and
wherein the first inner portion and the second inner portion extend in the first direction in the first one of the plurality of pixel regions, and the first inner portion and the second inner portion extend in the second direction in the second one of the plurality of pixel regions.

14. An image sensor, comprising:
a substrate that has a first surface and a second surface opposite to each other;
a photoelectric conversion portion in the substrate;
a pixel circuit adjacent to the first surface of the substrate; and
an isolation pattern that extends through at least a portion of the substrate,
wherein the photoelectric conversion portion includes a first conversion portion and a second conversion portion,
wherein the first conversion portion is at a first side of the photoelectric conversion portion in a first direction,
wherein the second conversion portion is at a second side of the photoelectric conversion portion opposite to the first side in the first direction,
wherein the pixel circuit includes a first transistor,
wherein the first transistor includes a first transfer transistor and a second transfer transistor,
wherein the first transfer transistor is electrically connected to the first conversion portion and is at a third side of the photoelectric conversion portion in a second direction that intersects the first direction, and
wherein the second transfer transistor is electrically connected to the second conversion portion and is at a fourth side of the photoelectric conversion portion opposite to the third side in the second direction.

15. The image sensor of claim 14, comprising:
a pixel region that includes the photoelectric conversion portion and the pixel circuit,
wherein the first transfer transistor and the second transfer transistor have a point-symmetrical shape in the pixel region, and have an asymmetrical shape in the first direction or the second direction.

16. The image sensor of claim 14, wherein the pixel circuit includes a second transistor and a third transistor,
wherein each transistor of the second transistor and the third transistor has a cross-sectional shape different from a cross-sectional shape of the first transistor, and
wherein, in a plan view, the third transistor is at a first portion overlapping the first conversion portion and is at the fourth side in the second direction, and the second transistor is at a second portion overlapping the second conversion portion and is at the third side in the second direction.

17. The image sensor of claim 14, comprising:
a floating diffusion region at an active region of the substrate adjacent to the first surface of the substrate,
wherein the pixel circuit includes a second transistor and a connection wiring, the second transistor has a second cross-sectional shape different from a first cross-sectional shape of the first transistor, and the connection wiring extends from a gate electrode of the second transistor and is electrically connected to the floating diffusion region in a plan view.

18. An image sensor, comprising:
a substrate that has a first surface and a second surface opposite to each other;
a plurality of pixel regions, each pixel region of the plurality of pixel regions including a photoelectric conversion portion in the substrate and a pixel circuit adjacent to the first surface of the substrate; and
an isolation pattern that extends through at least a portion of the substrate and includes an isolation portion, the isolation portion defining a region where the photoelectric conversion portion is disposed,
wherein the photoelectric conversion portion includes a first conversion portion and a second conversion portion,
wherein the first conversion portion is at a first side of the photoelectric conversion portion in a first direction,
wherein the second conversion portion is at a second side of the photoelectric conversion portion opposite to the first side in the first direction, and
wherein the pixel circuit has a point-symmetrical shape in a pixel region of the plurality of pixel regions, and has an asymmetrical shape in the first direction.

19. The image sensor of claim 18, wherein the pixel circuit includes a first transistor,
wherein the first transistor includes a first transfer transistor and a second transfer transistor, and
wherein the first transfer transistor and the second transfer transistor are at two opposite sides in a first diagonal direction inclined to the first direction.

20. The image sensor of claim 19, wherein the pixel circuit includes a second transistor and a third transistor,
wherein each transistor of the second transistor and the third transistor has a cross-sectional shape different from a cross-sectional shape of the first transistor, and
wherein the second transistor and the third transistor are at two opposite sides in a second diagonal direction that is inclined to the first direction and intersects the first diagonal direction.
